(19) United States
(12) Patent Application Publication
(10) Pub. No.: US 2008/0020208 A1
(43) Pub. Date: Jan. 24, 2008

(54) Conducting polymer composition, conductive film formed using the conducting polymer composition, and electronic device including the conductive film

(76) Inventors: Tae-Woo Lee, Yongin-si (KR); Jong-Jin Park, Yongin-si (KR); O-Hyun Kwon, Yongin-si (KR)

Correspondence Address: Robert E. Bushnell;Suite 300, 1522 K Street, N.W., Washington, DC, 20005, US

(21) Appl. No.: 11/729,794

(22) Filed: Mar. 30, 2007

(30) Foreign Application Priority Data
Jun. 7, 2006 (KR) 10-2006-0051084

(51) Int. Cl. B32B 27/00; H01B 1/12

(52) U.S. Cl. 428/411.1; 252/500; 428/500

(57) ABSTRACT

Provided is a conducting polymer composition including a conducting polymer and an ionic conjugated polymer. The conducting polymer composition includes the ionic conjugated polymer having a conjugated structure, in addition to the conducting polymer, and thus, can enhance hole injection and transport capability. Furthermore, ionization potential and work function can be easily adjusted by chemically tuning the backbone of the ionic conjugated polymer. In addition, the conducting polymer composition can be dissolved in water, alcohol, or a polar organic solvent, thereby enabling a solution process and rendering spin-coating easier.

### CROSS-REFERENCE TO RELATED PATENT APPLICATION AND CLAIM OR PRIORITY

This application claims priority from Korean Patent Application No. 10-2006-0051084, filed on Jun. 7, 2006, in the Korean Intellectual Property Office, the disclosure of which is incorporated herein in its entirety by reference.

### 1. FIELD OF THE INVENTION

The present invention relates to a conducting polymer composition and an electronic device including the conducting polymer composition. More particularly, the present invention relates to a conducting polymer composition which is improved in hole injection and transport capability, has good coating property and can be easily blended with other organic polymer due to homogeneous dissolution in water or an organic solvent, and is easy to adjust conductivity and work function, and to an electronic device including the conducting polymer composition and thus having high efficiency and long lifetime.

### 2. DESCRIPTION OF THE RELATED ART

Generally speaking, optoelectronic devices can be defined by the devices that convert light energy into electric energy and vice versa. Examples of optoelectronic devices include organic light-emitting devices, photovoltaic devices, electrochromic devices, electrophoretic devices, (photo)-transistors, etc. In order to increase the efficiency of optoelectronic devices by effectively increasing the mobility of charges (i.e., hole mobility and electron mobility) generated from electrodes of the optoelectronic devices, much research about formation of conducting polymer films has been recently conducted.

In particular, organic light-emitting devices (OLEDs) are active emission display devices that emit light by recombination of electrons and holes in a thin layer (hereinafter, referred to as “organic layer”) made of a fluorescent or phosphorescent organic compound when a current is applied to the organic layer. In order to enhance the efficiency of OLEDs and decrease a driving voltage, it is common to use, as an organic layer, a multi-layered structure of a hole injection layer, a light-emitting layer, an electron injection layer, etc. using a conducting polymer, rather than a light-emitting layer alone.

In particular, an aqueous solution of PEDOT (poly(3,4-ethylene dioxythiophene))-PSS (poly(4-styrene sulfonate)), which is commercially available under the trade name of Baytron-P (Bayer AG), has been widely used in 9 manufacturing of OLEDs to form a hole injection layer on an ITO (indium tin oxide) electrode using spin-coating. The PEDOT-PSS used as a hole injection material has the following structure:

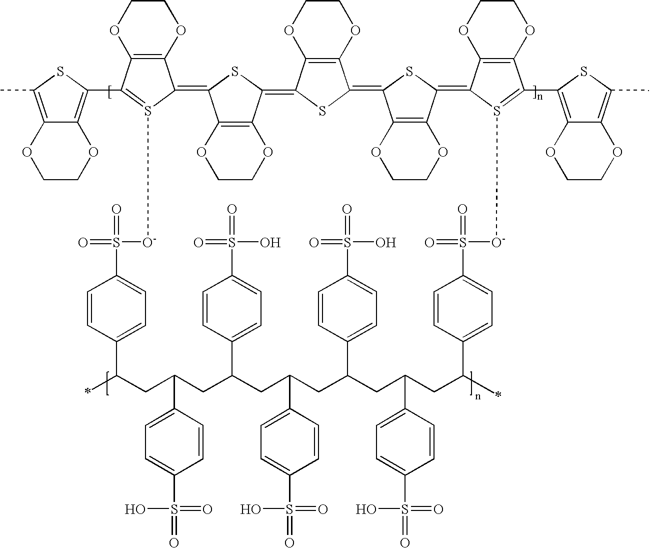

A conducting polymer composition of PEDOT/PSS in which polyacid of PSS is doped on a conducting polymer, PEDOT, is prepared by polymerization of EDOT monomers dissolved in an aqueous PSS solution. However, the obtained PEDOT/PSS polymer has a particle size of 50 nm or more dispersed in an aqueous phase, and thus, the conductivity, hole injection capability, and film uniformity of a thin film constituting an OLED, etc. significantly vary according to the particle size of the PEDOT/PSS polymer. Furthermore, the characteristics of the PEDOT/PSS dispersed solution vary according to a batch in which it is polymerized, thereby causing a performance deviation in the OLED.

In a PEDOT/PSS composition, PSS has high moisture uptake capability so that the moisture should be removed by heating the film under inert atmosphere during device fabrication process. Also, PSS may be decomposed by reaction with electrons and thus generate and diffuse the side product (e.g., sulfate) into a surrounding organic layer (e.g., light-emitting layer). As such, the diffusion of a material from a hole injection layer into a light-emitting layer causes exciton quenching, thereby leading to a reduction in efficiency and lifetime of OLEDs.

As described above, a PEDOT/PSS polymer is obtained by polymerization of EDOT monomers dissolved in an aqueous PSS solution. However, in the PEDOT/PSS polymer, PSS itself is not electrically conductive, thereby lowering the hole transport capability of the PEDOT/PSS polymer.

Therefore, in optoelectronic devices such as OLEDs, there is an increasing need to develop a new conducting polymer composition capable of providing satisfactory efficiency and lifetime.

### SUMMARY OF THE INVENTION

The present invention provides a conducting polymer composition which may be used for an electronic device.

The present invention provides a conducting polymer composition which has good coating property and can be easily blended with other organic polymer due to homogeneous dissolution in water or an organic solvent, and is easy to adjust electrical conductivity and work function.

The present invention also provides a conducting polymer film formed using the conducting polymer composition.

The present invention also provides an electronic device including the conducting polymer film and thus having high efficiency and long lifetime.

According to an aspect of the present invention, there is provided a conducting polymer composition including a conducting polymer and an ionic conjugated polymer.

The conducting polymer may be at least one selected from the group consisting of polythiophene, poly(3,4-ethylene dioxythiophene) (PEDOT), polyaniline, polypyrrole, polyacetylene, a derivative thereof, and a self-doped conducting polymer having a repeat unit represented by Formula 1 below with the degree of polymerization of 10 to 10,000,000:

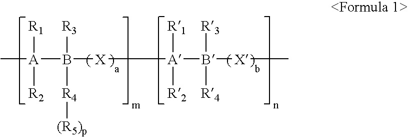

wherein 0<m<10,000,000, 0<n<10,000,000, 0<a<20, 0<b<20, and 2<p<10,000,000;

at least one of R₁, R₂, R₃, R′₁, R′₂, R′₃, and R′₄ includes an ion group, and A, B, A′, and B′ are each independently selected from C, Si, Ge, Sn, and Pb;

R₁, R₂, R₃, R′₁, R′₂, R′₃, and R′₄ are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, and hydrogen or a halogen atom is selectively attached to the carbon atoms of the groups;

R₄, X, and X′ are each independently selected from the group consisting of a bond, O, S, a substituted or unsubstituted C₁-C₃₀ alkylene group, a substituted or unsubstituted C₁-C₃₀ iminoalkylene group, a substituted or unsubstituted C₁-C₃₀ heteroalkylene group, a substituted or unsubstituted C₆-C₃₀ arylene group, a substituted or unsubstituted C₆-C₃₀ iminoarylene group, a substituted or unsubstituted C₆-C₃₀ arylalkylene group, a substituted or unsubstituted C₆-C₃₀ alkylarylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, a substituted or unsubstituted C₆-C₃₀ arylester group, and a substituted or unsubstituted C₆-C₃₀ heteroarylester group;

R₅ is a conjugated conducting polymer chain; and

X and X′ are each independently selected from the group consisting of a bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, and a substituted or unsubstituted C₆-C₃₀ arylester group, and hydrogen or a halogen atom is selectively attached to the carbon atoms of the groups.

The ionic conjugated polymer may have at least one repeat unit selected from the group consisting of compounds represented by Formulae 2a through 2ab below and may have the degree of polymerization of 2 to 10,000,000:

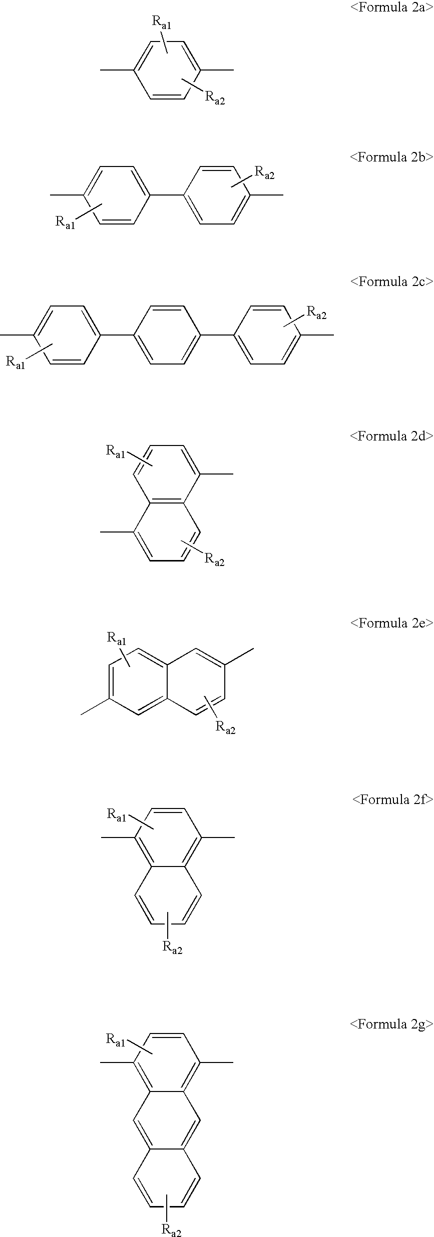

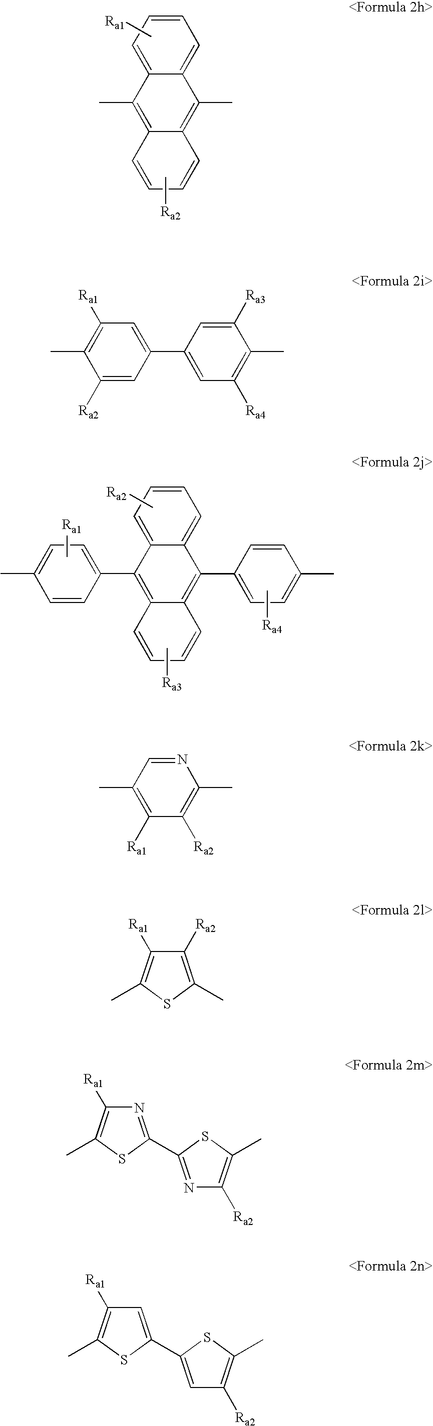

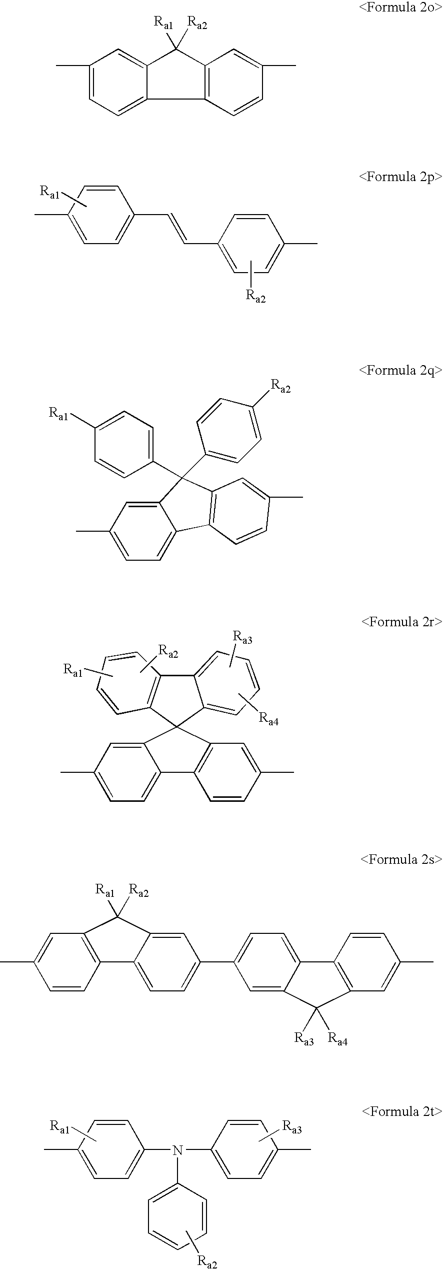

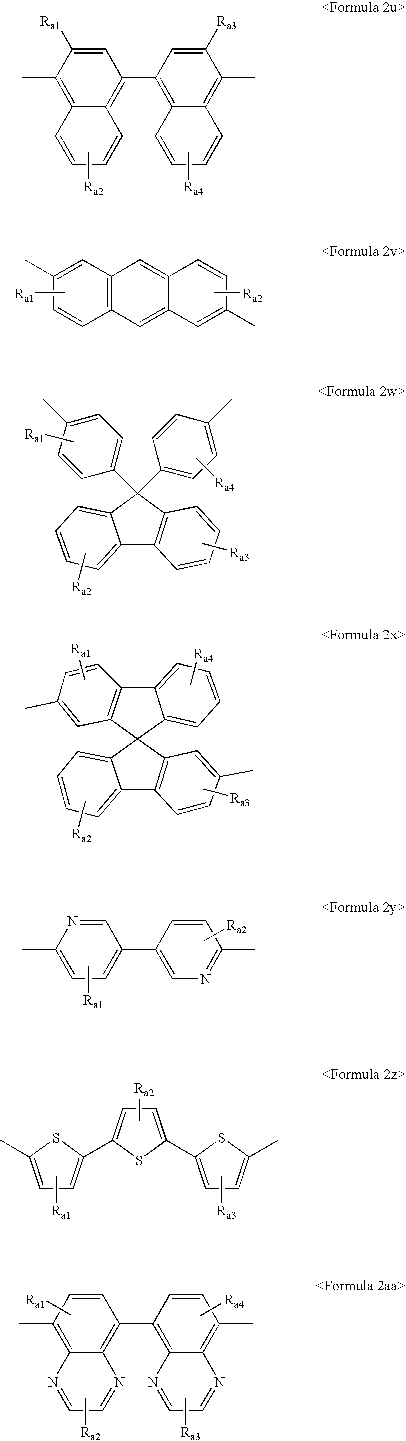

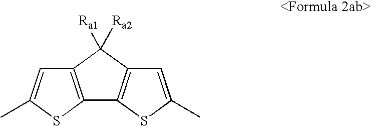

wherein,

Rₐ₁, Rₐ₂, Rₐ₃, and Rₐ₄ are each independently hydrogen, a C₁-C₁₂ alkyl group, a C₁-C₁₂ alkoxy group, a C₆-C₂₀ aryl group, —N(R′)(R″) where R′ and R″ are each independently hydrogen or a C₁-C₁₂ alkyl group, —R_{c}CO₂R_{b}, —R_{c}SO₃R_{b}, —OR_{c}SO₃R_{b}, or —R_{c}OR_{d}SO₃R_{b} where R_{c} and R_{d} are each a bond or a C₁-C₁₂ alkylene group, and R_{b} is H, Li, K, or Na, and

at least one of Rₐ₁, Rₐ₂, Rₐ₃, and Rₐ₄ is or includes an ion group.

According to another aspect of the present invention, there is provided a conductive film formed using the conducting polymer composition.

According to a further aspect of the present invention, there is provided an electronic device including the conductive film.

According to a still further aspect of the present invention, there is provided an organic light emitting device, including: a first electrode; a second electrode; an emissive layer between the first electrode and the second electrode; and a conductive layer between the first electrode and the emissive layer, the conductive layer formed of a conducting polymer composition comprising a conducting polymer and an ionic conjugated polymer.

A conducting polymer composition of the present invention includes an ionic conjugated polymer having a conjugated structure, in addition to a conducting polymer, and thus, can enhance hole injection and transport capability. Furthermore, ionization potential and work function can be easily adjusted by chemically tuning the backbone of the ionic conjugated polymer. In addition, the conducting polymer composition of the present invention can be dissolved in water, alcohol, or a polar organic solvent, thereby enabling a solution process and rendering spin-coating easier.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A through 1D are views illustrating the structures of organic light-emitting devices according to embodiments of the present invention.

### DETAILED DESCRIPTION OF THE INVENTION

The present invention will now be described more fully with reference to the accompanying drawings, in which exemplary embodiments of the invention are shown.

The present invention provides a conducting polymer composition including a conducting polymer and an ionic conjugated polymer.

The conducting polymer may be polythiophene, poly(3,4-ethylene dioxythiophene) (PEDOT), polyaniline, polypyrrole, polyacetylene, or a derivative thereof. The conducting polymer may also be a self-doped conducting polymer having a repeat unit represented by Formula 1 below with the degree of polymerization of 10 to 10,000,000:

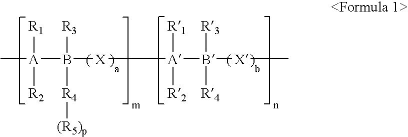

wherein 0<m<10,000,000, 0<n<10,000,000, 0<a<20, 0≦b≦20, and 2≦p≦10,000,000;

at least one of R₁, R₂, R₃, R′₁, R′₂, R′₃, and R′₄ includes an ion group, and A, B, A′, and B′ are each independently selected from C, Si, Ge, Sn, and Pb;

R₁, R₂, R₃, R′₁, R′₂, R′₃, and R′₄ are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, and hydrogen or a halogen atom is selectively attached to the carbon atoms of the groups;

R₄, X, and X′ are each independently selected from the group consisting of a bond, O, S, a substituted or unsubstituted C₁-C₃₀ alkylene group, a substituted or unsubstituted C₁-C₃₀ iminoalkylene group, a substituted or unsubstituted C₁-C₃₀ heteroalkylene group, a substituted or unsubstituted C₆-C₃₀ arylene group, a substituted or unsubstituted C₆-C₃₀ iminoarylene group, a substituted or unsubstituted C₆-C₃₀ arylalkylene group, a substituted or unsubstituted C₆-C₃₀ alkylarylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, a substituted or unsubstituted C₆-C₃₀ arylester group, and a substituted or unsubstituted C₆-C₃₀ heteroarylester group;

R₅ is a conjugated conducting polymer chain; and

X and X′ are each independently selected from the group consisting of a bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, and a substituted or unsubstituted C₆-C₃₀ arylester group, and hydrogen or a halogen atom is selectively attached to the carbon atoms of the groups.

The self-doped conducting polymer of Formula 1 includes one or more ion groups, and the ion groups may the same or different from each other.

In the self-doped conducting polymer of Formula 1, at least one of R₁, R₂, R₃, R′₁, R′₂, R′₃, and R′₄ may be a fluorine or a fluorine-substituted group.

R₅ can be any conjugated conducting polymer chain. Examples of R₅ include, but are not limited to, arylamine, aryl, fluorene, aniline, thiophene, phenylene, and acetylene.

The self-doped conducting polymer having the repeat unit of Formula 1 may be one selected from the group consisting of compounds represented by Formulae 3a through 3c below:

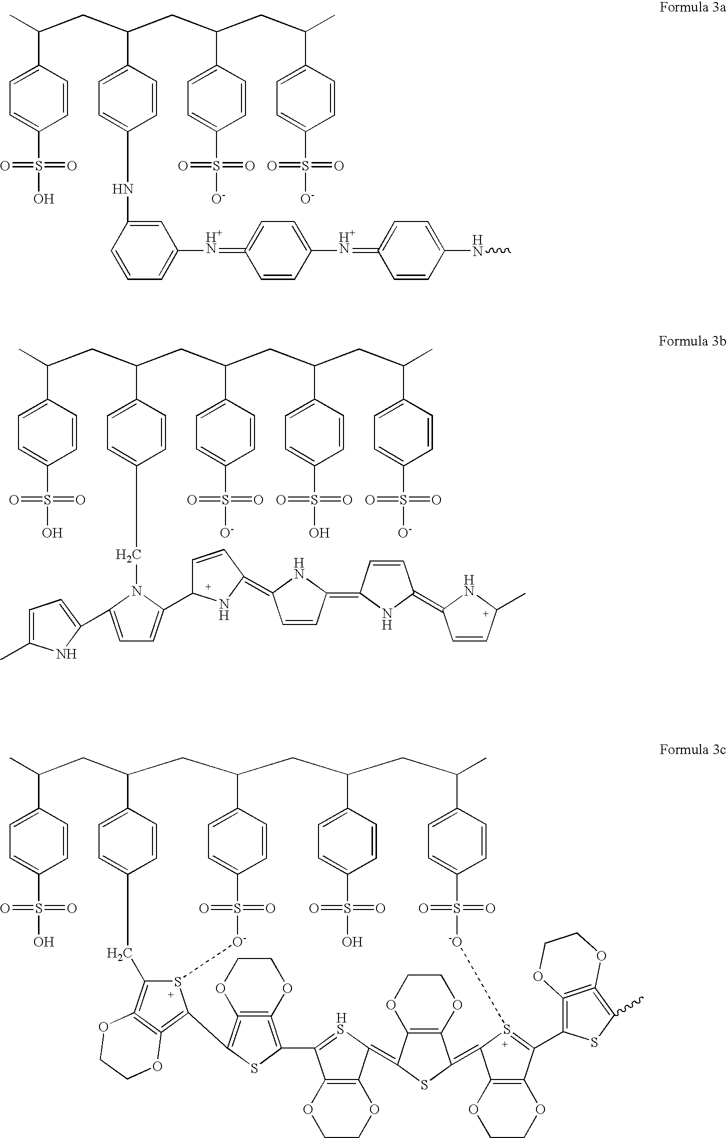

In the self-doped conducting polymer of Formula 1, a conducting polymer is grafted to a side chain of a polymer including an ion group, i.e., an ionomer.

As described above, in Formula 1, at least one hydrogen of R₁, R₂, R₃, R₄′, R₁′, R₂′, R₃′, and R₄′ may be substituted by an ion group, or an ion group itself may be directly attached to A, A′, B, or B′. An anion group that can be used herein may be PO₃²⁻, SO₃⁻, COO⁻, I⁻, CH₃COO⁻, etc., and a counter ion of the anion group may be a metal ion such as Na⁺, K⁺, Li⁺, Mg⁺2, Zn⁺2, or Al⁺3, or an organic ion such as H⁺, NH₄⁺, or CH₃(—CH₂—)ₙO⁺ (n is an integer of 0 to 50).

In the case of using two or more anion groups, the two or more anion groups may have different acidities according to monomer units. For example, when at least one of R₁, R₂, and R₃ is PO₃²⁻, at least one of R₁′, R₂′, R₃′, and R₄′ may be substituted by SO₃⁻, COO⁻, I⁻, or CH₃COO⁻. When at least one of R₁, R₂, and R₃ is SO₃⁻, at least one of R₁′, R₂′, R₃′, and R₄′ may be substituted by COO⁻, I⁻, or CH₃COO⁻.

The ionic conjugated polymer refers to an ion group-substituted polymer having a conjugated structure.

The ionic conjugated polymer may have at least one repeat unit selected from the group consisting of compounds represented by Formulae 2a through 2ab below and may have the degree of polymerization of 2 to 10,000,000:

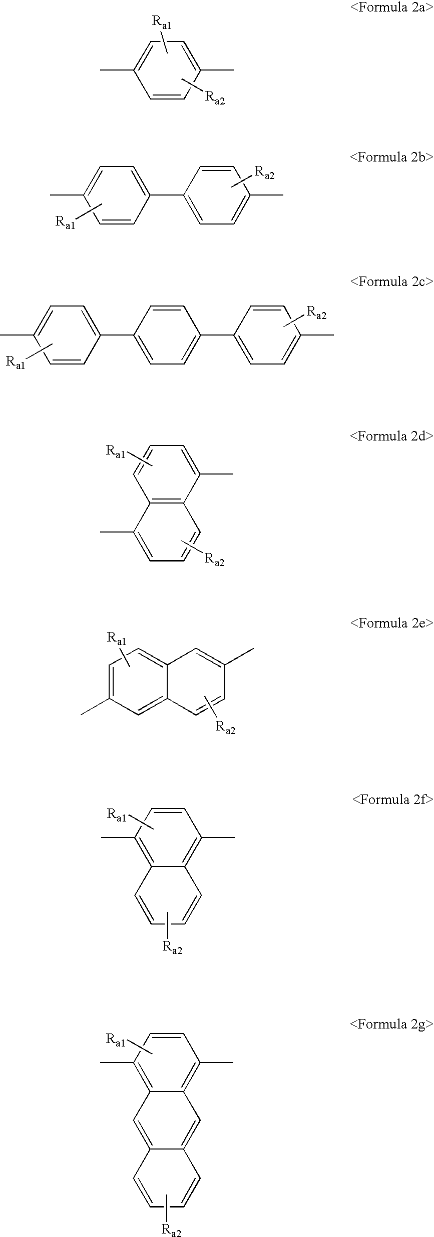

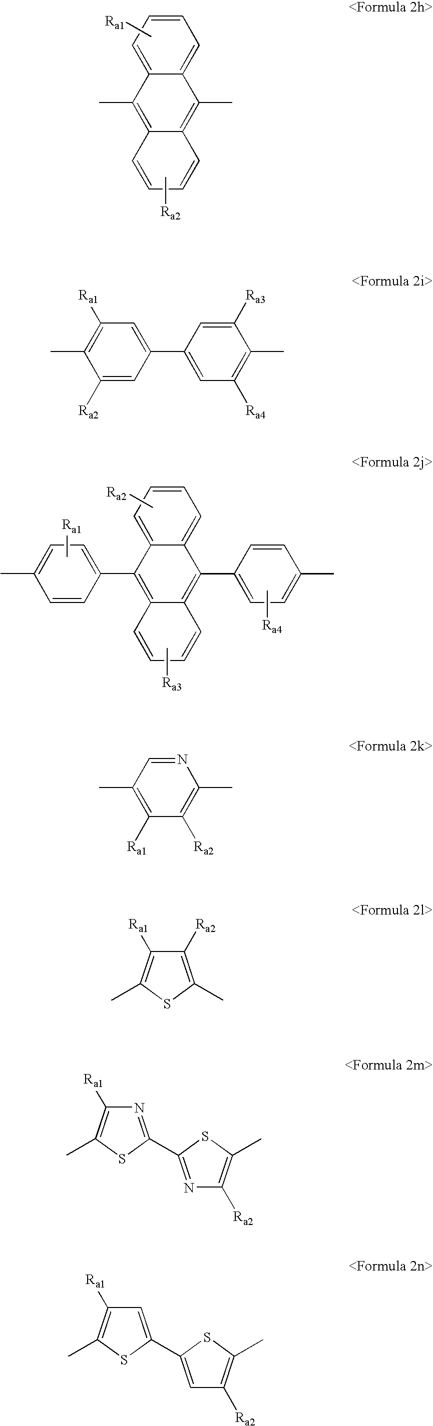

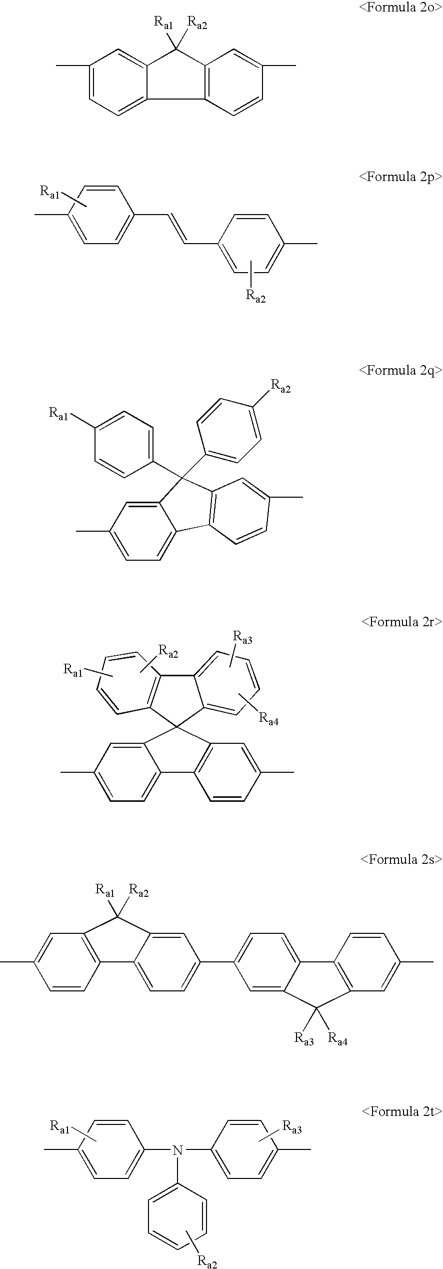

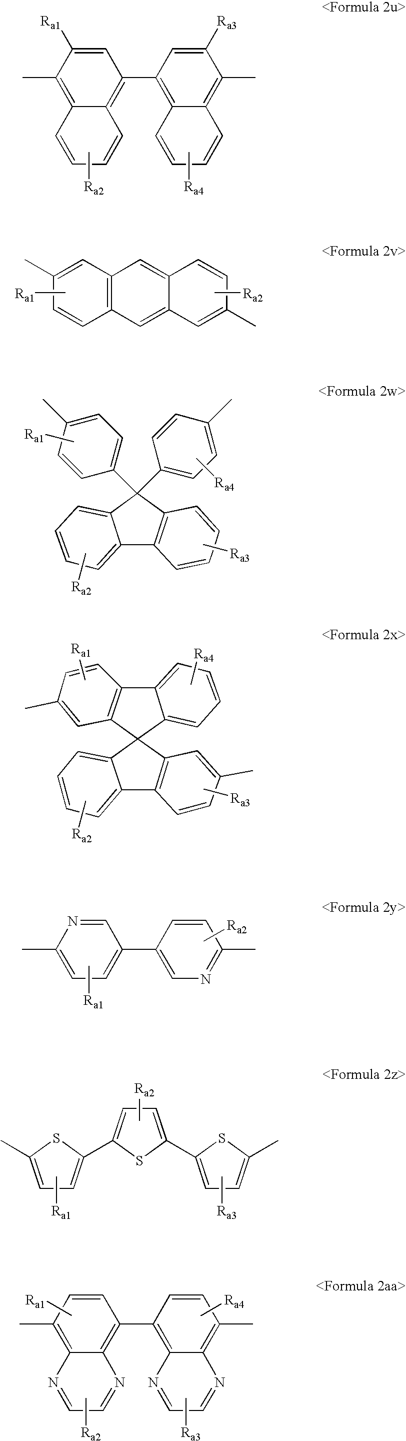

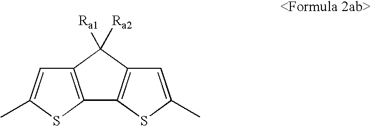

wherein Rₐ₁, Rₐ₂, Rₐ₃, and Rₐ₄ are each independently hydrogen, a C₁-C₁₂ alkyl group, a C₁-C₁₂ alkoxy group, a C₆-C₂₀ aryl group, —N(R′)(R″) where R′ and R″ are each independently hydrogen or a C₁-C₁₂ alkyl group, —R_{c}CO₂R_{b}, —R_{c}SO₃R_{b}, —OR_{c}SO₃R_{b}, or —R_{c}OR_{d}SO₃R_{b} where R_{c} and R_{d} are each a bond or a C₁-C₁₂ alkylene group, and R_{b} is H, Li, K, or Na, and

at least one of Rₐ₁, Rₐ₂, Rₐ₃, and Rₐ₄ is or includes an ion group.

Preferably, the ion group may include an anion group selected from the group consisting of PO₃²⁻, SO₃⁻, COO⁻, I⁻, and CH₃COO⁻, and a cation group which is paired with the anion group and selected from the group consisting of a metal ion such as Na⁺, K⁺, Li⁺, Mg⁺², Zn⁺², or Al⁺³, and an organic ion such as H⁺, NH₄⁺, or CH₃(—CH₂—)ₙO⁺ (n is a natural number of 1 to 50).

The ionic conjugated polymer may include at least one fluorine or at least one fluorine-substituted group.

Examples of the ionic conjugated polymer include compounds represented by Formulae 4a through 4f below:

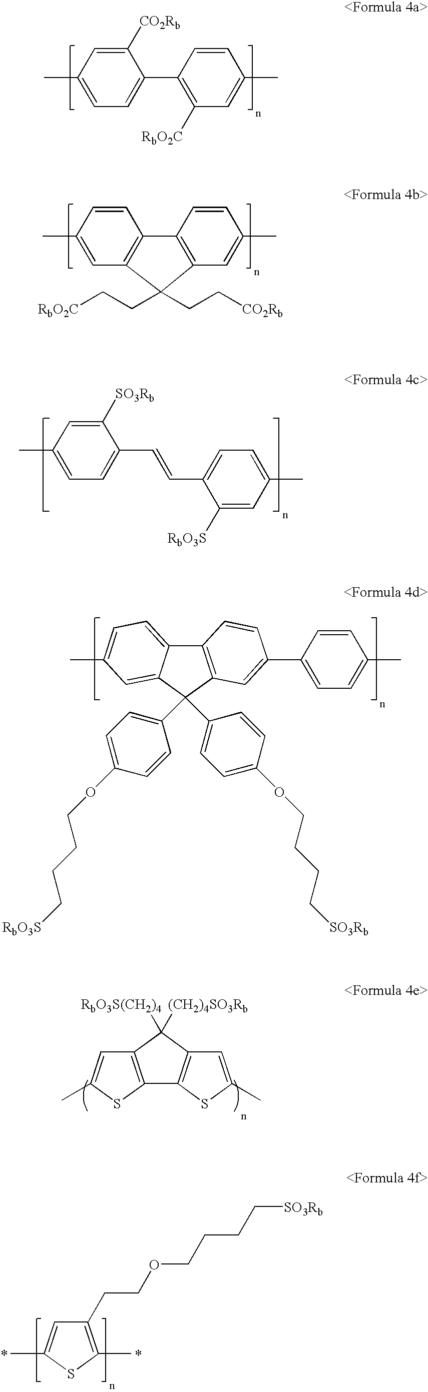

wherein R_{b} is H, Li, K, or Na, and n is the degree of polymerization of 2 to 10,000,000.

In the conducting polymer composition of the present invention, the content of the ionic conjugated polymer may be 10 to 3,000 parts by weight, more preferably, 200 to 1,600 parts by weight, based on 100 parts by weight of the conducting polymer. If the content of the ionic conjugated polymer is less than 10 parts by weight based on 100 parts by weight of the conducting polymer, conductivity may not be sufficient due to poor doping of the conducting polymer. On the other hand, if it exceeds 3,000 parts by weight, the conducting polymer composition may be susceptible to moisture due to too many ion groups.

In a conventional PEDOT/PSS composition, PSS itself does not have electrical conductivity. In contrast, the conducting polymer composition of the present invention includes the ionic conjugated polymer, and thus, shows better hole injection and transport capability than the conventional PEDOT/PSS composition. At this time, the ionization potential and work function can be easily adjusted by appropriately controlling the backbone of the ionic conjugated polymer.

The conducting polymer composition of the present invention may further include an ionomer having a different structure from the conducting polymer and the ionic conjugated polymer. The ionomer may include an ion group of a polyacid. Also, the ionomer may be a partially fluorinated ionomer or a perfluorinated ionomer.

In the conducting polymer composition of the present invention, the content of the ionomer may be from 10 to 3,000 parts by weight, more preferably, from 200 to 1,600 parts by weight, based on 100 parts by weight of the conducting polymer. If the content of the ionomer is less than 10 parts by weight based on 100 parts by weight of the conducting polymer, an addition effect of the ionomer may be insufficient. On the other hand, if it exceeds 3,000 parts by weight, conductivity may be significantly reduced.

The ionomer may be one selected from polymers represented by Formulae 5 through 19 below:

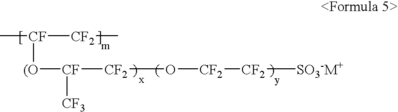

wherein m is a number of 1 to 10,000,000, x and y are each independently a number of 0 to 10, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

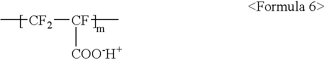

wherein m is a number of 1 to 10,000,000;

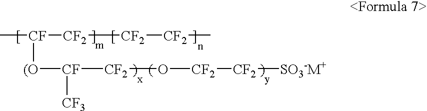

wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

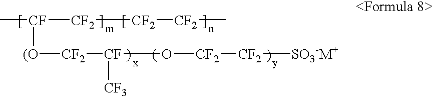

wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

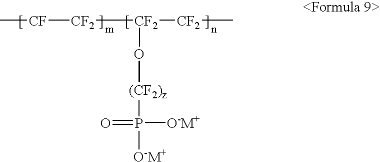

wherein 0<m≦10,000,000, 0≦n<10,000,000, z is a number of 0 to 20, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

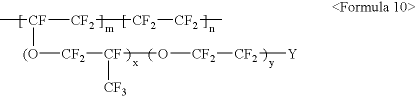

wherein 0<m≦10,000,000, 0≦n<10,000,000, x and y are each independently a number of 0 to 20, and Y is one selected from —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

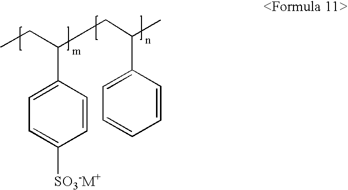

wherein 0≦m<10,000,000, 0≦n<10,000,000, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

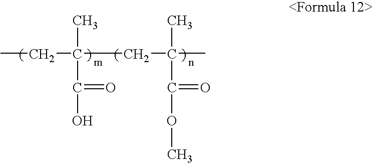

wherein 0<m≦10,000,000 and 0≦n<10,000,000;

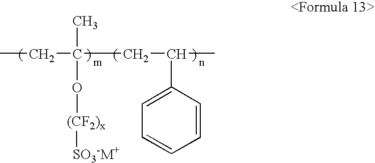

wherein 0<m≦10,000,000, 0≦n<10,000,000, x is a number of 0 to 20, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

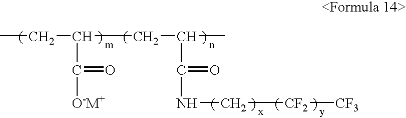

wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

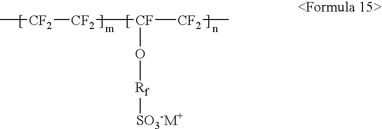

wherein 0≦m<10,000,000, 0<n≦10,000,000, R_{f} is —(CF₂)ₙ— (z is an integer of 1 to 50 except 2), —(CF₂CF₂O)_{z}CF₂CF₂— (z is an integer of 1 to 50), or —(CF₂CF₂CF₂O)_{z}CF₂CF₂— (z is an integer of 1 to 50), and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

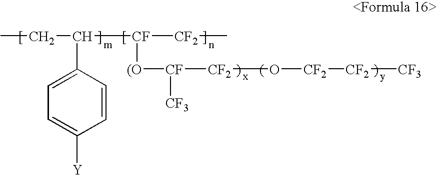

wherein 0≦m<10,000,000, 0<n≦10,000,000, x and y are each independently a number of 0 to 20, and Y is one selected from —SO₃⁻M⁺, —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is an alkyl group, i.e., CH₃(CH₂)ₙ⁻ where n is an integer of 0 to 50);

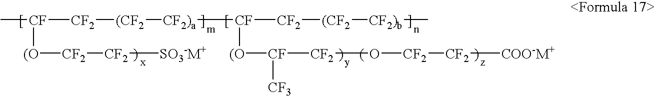

wherein 0<m<10,000,000, 0<n<10,000,000, 0≦a≦20, 0≦b≦20, x, y and z are each independently a number of 0 to 5, and M⁺ is Na⁺, K⁺, Li⁺, H⁺, CH₃(CH₂)ₙNH₃⁺ (n is an integer of 0 to 50), NH₄⁺, NH₂⁺, NHSO₂CF₃⁺, CHO⁺, C₂H₅OH⁺, CH₃OH⁺, or RCHO⁺ (R is a C₁-C₅₁ alkyl group);

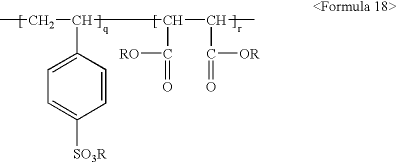

wherein 0≦q<10,000,000, 0<r≦10,000,000, and R is H; and

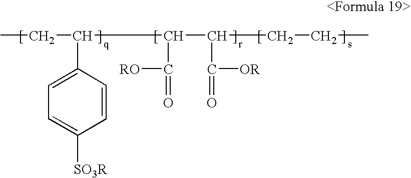

wherein 0≦q<10,000,000, 0<r≦10,000,000, 0<s≦10,000,000, and R is H.

Examples of the unsubstituted alkyl group used herein include, but are not limited to, straight or branched methyl, ethyl, propyl, isobutyl, sec-butyl, tert-butyl, pentyl, iso-amyl, and hexyl. One or more hydrogen atoms on the alkyl group may be substituted by a halogen atom, a hydroxy group, a nitro group, a cyano group, a substituted or unsubstituted amino group (—NH₂, —NH(R), or —N(R′)(R″) where R′ and R″ are each independently a C₁-C₁₀ alkyl group), an amidino group, hydrazine, hydrazone, a carboxyl group, a sulfonyl group, a phosphonyl group, a C₁-C₂₀ alkyl group, a C₁-C₂₀ halogenated alkyl group, a C₁-C₂₀ alkenyl group, a C₁-C₂₀ alkynyl group, a C₁-C₂₀ heteroalkyl group, a C₆-C₂₀ aryl group, a C₆-C₂₀ arylalkyl group, a C₆-C₂₀ heteroaryl group, or a C₆-C₂₀ heteroarylalkyl group.

The heteroalkyl group as used herein refers to an alkyl group as defined above wherein one or more carbon atoms, preferably 1-5 carbon atoms, in the backbone are substituted by a heteroatom such as an oxygen atom, a sulphur atom, a nitrogen atom, or a phosphorus atom.

The aryl group as used herein refers to a carbocyclic aromatic system containing one or more aromatic rings. The rings may be attached to each other as a pendant group or may be fused. Examples of the aryl group include, but are not limited to, aromatic groups such as phenyl, naphthyl, and tetrahydronaphthyl. One or more hydrogen atoms on the aryl group may be substituted by one or more substituents as those mentioned above about the alkyl group.

The heteroaryl group as used herein refers to a 5 to 30-membered, carbocyclic aromatic system containing one, two or three hetero atoms selected from N, O, P, and S. The rings may be attached to each other as a pendant group or may be fused. One or more hydrogen atoms on the heteroaryl group may be substituted by one or more substituents as those mentioned above about the alkyl group.

The alkoxy group as used herein refers to an —O-alkyl radical. Here, the “alkyl” is as defined above. Examples of the alkoxy group include, but are not limited to, methoxy, ethoxy, propoxy, isobutyloxy, sec-butyloxy, pentyloxy, iso-amyloxy, and hexyloxy. One or more hydrogen atoms on the alkoxy group may be substituted by one or more substituents as′those mentioned above about the alkyl group.

The heteroalkoxy group as used herein refers to an alkoxy group containing at least one hetero atom, e.g., oxygen, sulfur, or nitrogen in the alkyl chain. For example, the heteroalkoxy group may be CH₃CH₂OCH₂CH₂O—, C₄H₉OCH₂CH₂OCH₂CH₂O—, CH₃O(CH₂CH₂O)ₙH, etc.

The arylalkyl group as used herein refers to an aryl group as defined above wherein one or more hydrogen atoms are substituted by a lower alkyl radical, e.g., methyl, ethyl, or propyl. Examples of the arylalkyl group include benzyl and phenylethyl. One or more hydrogen atoms on the arylalkyl group may be substituted by one or more substituents as those mentioned above about the alkyl group.

The heteroarylalkyl group as used herein refers to a heteroaryl group wherein one or more hydrogen atoms are substituted by a lower alkyl group. The “heteroaryl” on the heteroarylalkyl group is as defined above. One or more hydrogen atoms on the heteroarylalkyl group may be substituted by one or more substituents as those mentioned above about the alkyl group.

The aryloxy group as used herein refers to an —O-aryl radical. Here, the “aryl” is as defined above. Examples of the aryloxy group include phenoxy, naphthoxy, anthracenyloxy, phenanthrenyloxy, fluorenyloxy, and indenyloxy. One or more hydrogen atoms on the aryloxy group may be substituted by one or more substituents as those mentioned above about the alkyl group.

The heteroaryloxy group as used herein refers to an —O-heteroaryl radical. Here, the “heteroaryl” is as defined above. Examples of the heteroaryloxy group include benzyloxy and phenylethyloxy. One or more hydrogen atoms on the heteroaryloxy group may be substituted by one or more substituents as those mentioned above about the alkyl group.

The cycloalkyl group as used herein refers to a monovalent monocyclic system having 5-30 carbon atoms. One or more hydrogen atoms on the cycloalkyl group may be substituted by one or more substituents as those mentioned above about the alkyl group.

The heterocycloalkyl group as used herein refers to a 5 to 30-membered, monovalent monocyclic system containing one, two or three hetero atoms selected from N, O, P, and S. One or more hydrogen atoms on the cycloalkyl group may be substituted by one or more substituents as those mentioned above about the alkyl group.

The alkylester group as used herein refers to an alkyl group having an ester moiety appended thereto. Here, the “alkyl” is as defined above.

The heteroalkylester group as used herein refers to a heteroalkyl group having an ester moiety appended thereto. Here, the “heteroalkyl” is as defined above.

The arylester group as used herein refers to an aryl group having an ester moiety appended thereto. Here, the “aryl” is as defined above.

The heteroarylester group as used herein refers to a heteroaryl group having an ester moiety appended thereto. Here, the “heteroaryl” is as defined above.

The amino group as used herein is —NH₂, —NH(R), or —N(R′)(R″) where R′ and R″ are each independently a C₁-C₁₀ alkyl group.

The halogen as used herein is fluorine, chlorine, bromine, iodine, or astatine. Fluorine is preferred.

In the present invention, in order to further enhance the level of crosslinkage between the conducting polymer and the ionic conjugated polymer, the conducting polymer composition of the present invention may further include a physical crosslinking agent and/or a chemical crosslinking agent.

The physical crosslinking agent forms physical crosslinking between polymer chains without chemical bonds, and may be small molecule or polymer containing a hydroxy group. For example, the physical crosslinking agent may be a small molecule such as glycerol or butanol or a polymer such as polyvinylalcohol, polyvinylphenol, polyethyleneglycol, polyethyleneimine, polyvinylpyrolidone, etc.

The content of the physical crosslinking agent may be from 0.001 to 5 parts by weight, more preferably, from 0.1 to 3 parts by weight, based on 100 parts by weight of the conducting polymer composition. If the content of the physical crosslinking agent is less than 0.001 parts by weight, an addition amount of the physical crosslinking agent is too small to be used as a crosslinking agent. On the other hand, if it exceeds 5 parts by weight, the film morphology of an organic layer may worsen.

The chemical crosslinking agent is a chemical crosslinking compound capable of in-situ polymerizing and producing an interpenetrating polymer network (IPN). A silane-based compound, e.g., tetraethyloxysilane (TEOS), is mainly used as the chemical crosslinking agent. In addition, the chemical crosslinking agent may be a polyaziridine-based compound, a melamine-based compound, or an epoxy-based compound.

The content of the chemical crosslinking agent may be from 0.01 to 50 parts by weight, more preferably, from 1 to 10 parts by weight, based on 100 parts by weight of the conducting polymer composition. If the content of the chemical crosslinking agent is less than 0.001 parts by weight, crosslinking may be insufficiently performed. On the other hand, if it exceeds 50 parts by weight, the conductivity of an organic layer may be significantly lowered.

The conducting polymer composition according to the present invention may further include metal nanoparticles. The metal nanoparticles serve to further enhance the conductivity of the conducting polymer composition.

The metal nanoparticles may be at least one selected from the group consisting of Au, Ag, Cu, Pd, and Pt nanoparticles. The metal nanoparticles may have an average particle size of 5 to 20 nm. If the average particle size of the metal nanoparticles is less than 5 nm, the nanoparticles may be self-agglomerated. On the other hand, if it exceeds 20 nm, it may be impossible to control the surface roughness of an organic layer.

The conducting polymer composition according to the present invention may further include inorganic nanoparticles or carbon nanotubes. When used to form an organic layer, the inorganic nanoparticles are dispersed in the organic layer and serve to assist conduction in a network of conjugated compounds or to reinforce the network of the conjugated compounds.

The inorganic nanoparticles may be at least one selected from the group consisting of SiO₂ and TiO₂ nanoparticles. The inorganic nanoparticles may have an average particle size of 5 to 100 nm. If the average particle size of the inorganic nanoparticles is less than 5 nm, the nanoparticles may be self-agglomerated. On the other hand, if it exceeds 100 nm, it may be impossible to control the surface roughness of an organic layer.

The conducting polymer composition of the present invention may further include a siloxane- and/or silsesquioxane-based compound.

The siloxane-based compound serves to form a network of conducting polymer chains. Thus, in a film made of the conducting polymer composition, the motility of conducting polymer chains is restricted, and the migration of various impurities (e.g., impurities from an anode) and moisture into another layer can be prevented. Therefore, it is possible to enhance the electrical properties and lifetime of an electronic device including a film made of the conducting polymer composition.

The siloxane-based compound may be a compound represented by Formula 20 or 21 below:

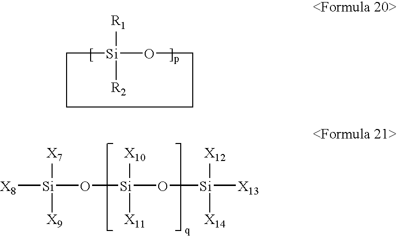

wherein,

R₁ and R₂ are each independently —CH₂(CH₂)ₘSiX₁X₂X₃, —O—SiX₄X₅X₆, a crosslinkable unit, a hole transport unit, an electron transport unit, an emissive unit, hydrogen, a halogen atom, a C₁-C₂₀ alkyl group, or a C₆-C₃₀ aryl group, and at least one of R₁ and R₂ is —CH₂(CH₂)ₘSiX₁X₂X₃, —O—SiX₄X₅X₆, or a crosslinkable unit;

X₁, X₂, X₃, X₄, X₅, X₆, X₇, X₈, X₉, X₁₀, X₁₁, X₁₂, X₁₃, and X₁₄ are each independently a crosslinkable unit, a hole transport unit, an electron transport unit, an emissive unit, hydrogen, or a C₁-C₂₀ alkyl group, at least one of X₁, X₂, and X₃ is a crosslinkable unit, at least one of X₄, X₅, and X₆ is a crosslinkable unit, and at least one of X₇, X₈, X₉, X₁₀, X₁₁, X₁₂, X₁₃, and X₁₄ is a crosslinkable unit;

p is an integer of 3 to 8;

m is an integer of 1 to 10;

q is 0 or an integer of 1 to 10;

q“X₁₀”s may be the same or different from each other;

q“X₁₁”s may be the same or different from each other;

r“D”s may the same or different from each other; and

r is 0 or an integer of 1 to 10.

A film including the silsesquioxane-based compound can effectively control hole transport or electron transport, and has good film smoothness. Therefore, an organic light-emitting device including the film can have good electrical characteristics.

The silsesquioxane-based compound may be a compound represented by Formula 22 below:

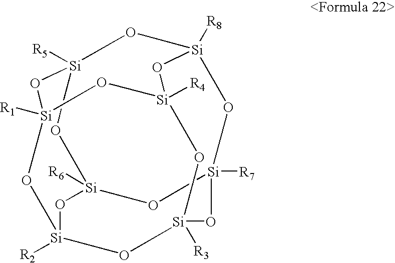

wherein R₁, R₂, R₃, R₄, R₅, R₆, R₇, and R₈ are each independently a hole transport unit, an electron transport unit, or a crosslinkable unit, and at least one of R₁, R₂, R₃, R₄, R₅, R₆, R₇, and R₈ is a crosslinkable unit.

The conducting polymer composition of the present invention may further include a stabilizer, an ionic liquid, or a compatibilizer.

The present invention also provides a conductive film (also referred to as a conductive layer) formed using the conducting polymer composition of the present invention.

The conductive film made of the conducting polymer composition can be formed as follows. For example, a conducting polymer composition is dissolved or dispersed in a solvent, and the resultant conducting polymer composition solution is coated on a substrate, dried, and/or heated.

The solvent serves to provide a predetermined viscosity to the conducting polymer composition. The solvent is not particularly limited provided that it can dissolve or disperse the conducting polymer composition. Examples of the solvent include, but are not limited to, water, alcohol, toluene, xylene, chlorobenzene, chloroform, dichloroethane, dimethylformamide, and dimethylsulfoxide. The coating of the conducting polymer composition on a substrate may be performed using various coating methods known in the art, e.g., spin coating, dip coating, ink-jet printing, nozzle printing, etc. The drying and/or the heating of the coating layer complete the conductive film made of the conducting polymer composition.

The conductive film made of the conducting polymer composition is suitable to be used as conductive films of various electronic devices. Examples of the electronic devices include, but are not limited to, organic light-emitting devices, photovoltaic devices, electrochromic devices, electrophoretic devices, organic thin film transistors, and organic memory devices.

In particular, with respect to organic light-emitting devices, the conducting polymer composition is used in formation of a hole injection layer, and thus, the hole injection layer can achieve the balanced and efficient injection of holes into emissive polymers, thereby increasing the emission intensity and efficiency of the organic light-emitting devices.

With respect to photovoltaic devices, the conducting polymer composition is used for an electrode or an electrode buffer layer, thereby increasing quantum efficiency. With respect to organic thin film transistors, the conducting polymer composition is used as an electrode material for gates, source/drain electrodes, etc.

An organic light-emitting device using the conducting polymer composition of the present invention and a manufacturing method thereof will now be described.

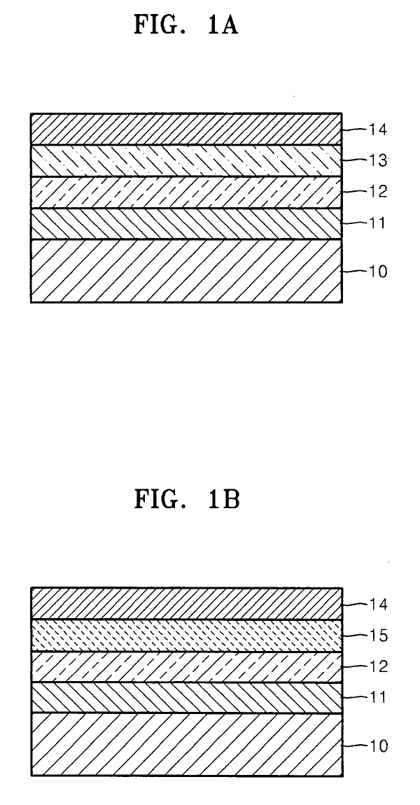

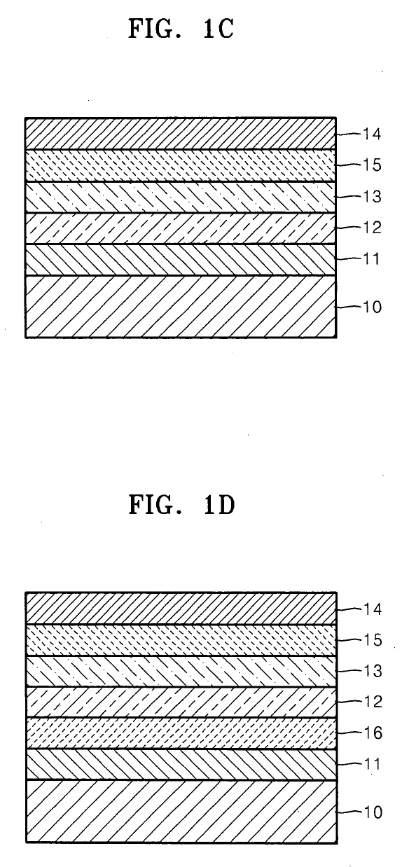

FIGS. 1A through 1D are schematic views illustrating the structures of organic light-emitting devices according to exemplary embodiments of the present invention.

Referring to FIG. 1A, a light-emitting layer 12 is formed on a first electrode 10. A hole injection layer (HIL) 11 (also called “buffer layer”) including a conducting polymer composition of the present invention is interposed between the first electrode 10 and the light-emitting layer 12. A hole blocking layer (HBL) 13 is formed on the light-emitting layer 12, and a second electrode 14 is formed on the hole blocking layer 13.

Referring to FIG. 1B, an organic light-emitting device has the same structure as that illustrated in FIG. 1A except that an electron transport layer (ETL) 15 is formed on a light-emitting layer 12.

Referring to FIG. 1C, an organic light-emitting device has the same structure as that illustrated in FIG. 1A except that a hole blocking layer (HBL) 13 and an electron transport layer 15 are sequentially formed on a light-emitting layer 12.

Referring to FIG. 1D, an organic light-emitting device has the same structure as that illustrated in FIG. 1C except that a hole transport layer 16 is further formed between a hole injection layer 11 and a light-emitting layer 12. Here, the hole transport layer 16 serves to prevent the penetration of impurities from the hole injection layer 11 into the light-emitting layer 12.

The organic light-emitting devices having the structures illustrated in FIGS. 1A through 1D can be manufactured using a non-limiting method commonly known in the art.

Hereinafter, a method of manufacturing an organic light-emitting device according to an embodiment of the present invention will be described.

First, a first electrode is patterned on a substrate. Here, the substrate may be a substrate commonly used in organic EL devices. Preferably, the substrate may be a glass substrate or a transparent plastic substrate which is excellent in transparency, surface roughness, handling property, and water repulsion. The thickness of the substrate may range from 0.3 to 1.1 mm.

A material forming the first electrode is not particularly limited. In a case where the first electrode is used as an anode, the first electrode may be made of a conductive metal promoting hole injection or its oxide, e.g., ITO (Indium Tin Oxide), IZO (Indium Zinc Oxide), nickel (Ni), platinum (Pt), gold (Au), or iridium (Ir).

The substrate on which the first electrode is formed is cleaned and treated with UV/ozone. At this time, the cleaning may be performed using an organic solvent such as isopropanol (IPA) or acetone.

A hole injection layer including a conducting polymer composition of the present invention is formed on the first electrode. Thus-formed hole injection layer can reduce a contact resistance between the first electrode and a light-emitting layer to be formed, and enhance the injection capability of holes from the first electrode into the light-emitting layer, thereby enhancing the driving voltage and lifetime characteristics of a device.

The hole injection layer is formed by spin-coating a hole injection layer forming composition obtained by dissolving or dispersing a conducting polymer composition of the present invention in a solvent on the first electrode followed by drying. Here, the hole injection layer forming composition is diluted to a concentration of 0.5 to 10 wt % using an organic solvent such as water, alcohol, dimethylformamide, dimethylsulfoxide, or dichloroethane.

The thickness of the hole injection layer may be 5 to 1,000 nm, more preferably, 10 to 100 nm. Preferably, the thickness of the hole injection layer may be 50 nm. If the thickness of the hole injection layer is less than 5 nm, hole injection may not be sufficiently performed due to a too thin thickness. On the other hand, if it exceeds 1,000 nm, light transmittance may be lowered.

A light-emitting layer is formed on the hole injection layer. A light-emitting layer material is not particularly limited. In more detail, blue light-emitting materials may be oxadiazole dimer dyes (Bis-DAPOXP)), spiro compounds (Spiro-DPVBi, Spiro-6P), triarylamine compounds, bis(styryl)amine (DPVBi, DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-tolylamino)styryl]biphenyl (DPAVBi), 4-(di-p-tolylamino)-4′-[(di-p-tolylamino)styryl]stilbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FlrPic), etc., green light-emitting materials may be 3-(2-benzothiazolyl)-7-(diethylamino)coumarin (Coumarin 6), 2,3,6,7-tetrahydro-1,1,7,7,-tetramethyl-1H,5H,11H-10-(2-benzothiazolyl)quinolizino-[9,9a,1gh]coumarin (C545T), N,N′-dimethyl-quinacridone (DMQA), tris(2-phenylpyridine)iridium (III) (Ir(ppy)₃), etc., and red light-emitting materials may be tetraphenylnaphthacene (Rubrene), tris(1-phenylisoquinoline)iridium (III) (Ir(piq)₃), bis(2-benzo[b]thiophene-2-yl-pyridine) (acetylacetonate)iridium (III) (Ir(btp)₂(acac)), tris(dibenzoylmethane)phenanthroline europium (III) (Eu(dbm)₃(phen)), tris[4,4′-di-tert-butyl-(2,2′)-bipyridine]ruthenium (III) complex (Ru(dtb-bpy)₃*2(PF₆)), DCM1, DCM2, Eu(thenoyltrifluoroacetone)₃ (Eu(TTA)₃, butyl-6-(1,1,7,7-tetramethyljulolidyl-9-enyl)-4H-pyran (DCJTB), etc. Furthermore, polymer light-emitting materials may include polymers such as phenylenes, phenylene vinylenes, thiophenes, fluorenes, and spiro-fluorenes, and nitrogen-containing aromatic compounds, but the present invention is not limited thereto.

The thickness of the light-emitting layer may be 10 to 500 nm, preferably, 50 to 120 nm. Particularly, the thickness of a blue light-emitting layer may be 70 nm. If the thickness of the light-emitting layer is less than 10 nm, leakage current may increase, thereby decreasing efficiency and lifetime. On the other hand, if it exceeds 500 nm, an increase rate in driving voltage may increase.

In some cases, a composition for forming the light-emitting layer may further include a dopant. At this time, the content of the dopant varies according to a light-emitting layer material, but may be 30 to 80 parts by weight based on the total weight (100 parts by weight) of the light-emitting layer material (a host and the dopant). If the content of the dopant is outside the above range, the emission characteristics of organic light-emitting devices may be lowered. Examples of the dopant include arylamines, perylene-based compounds, pyrrole-based compounds, hydrazone-based compounds, carbazole-based compounds, stilbene-based compounds, Starburst-based compounds, and oxadiazole-based compounds.

A hole transport layer may be selectively formed between the hole injection layer and the light-emitting layer.

A hole transport layer material is not particularly limited, but may be at least one selected from the group consisting of hole transport compounds having a carbazole group, a phenoxazine group, a phenothiazine group, and/or an arylamine group, phthalocyanine-based compounds, and triphenylene derivatives. In more detail, the hole transport layer may be made of at least one selected from 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-yl)-N,N′-diphenyl benzidine(a-NPD), N,N′-diphenyl-N,N′-bis(1-naphthyl)-(1,1′-biphenyl)-4,4′-diamine (NPB), IDE320 (Idemitsu), poly(9,9-dioctylfluorene-co-N-(4-butylphenyl)diphenylamine) (TFB), and poly(9,9-dioctylfluorene-co-bis-N,N-(4-butylphenyl)-bis-N,N-phenyl-1,4-phenylenedia mine (PFB), but the present invention is not limited to the illustrated examples.

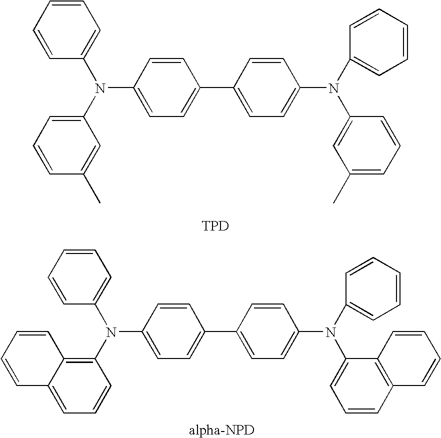

The hole transport layer may be formed to a thickness of 1 to 100 nm, preferably, 5 to 50 nm. Preferably, the hole transport layer may be formed to a thickness of 30 nm or less. If the thickness of the hole transport layer is less than 1 nm, hole transport capability may be lowered due to a too thin thickness. On the other hand, if it exceeds 100 nm, a driving voltage may increase.

A hole blocking layer and/or an electron transport layer are/is formed on the light-emitting layer using a deposition or spin-coating process. The hole blocking layer serves to prevent the migration of excitons formed from a light-emitting material into the electron transport layer or the migration of holes into the electron transport layer.

A hole blocking layer material may be selected from phenanthrolines (e.g.: BCP, UDC), imidazoles (e.g.: TPBI), triazoles, oxadiazoles (e.g.: PBD), aluminum complexes (BAlq, UDC).

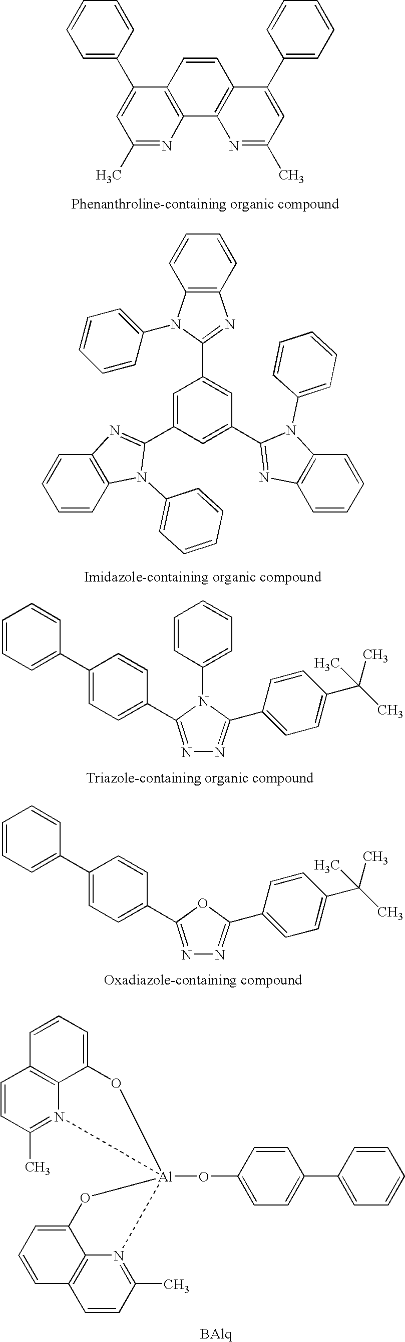

An electron transport layer material may be selected from oxazoles, isoxazoles, triazoles, isothiazoles, oxadiazoles, thiadiazoles, perylenes, aluminum complexes (e.g.: Alq3 (tris(8-quinolinolato)-aluminum), BAlq, SAlq, or Almq3), and gallium complexes (e.g.: Gaq′2OPiv, Gaq′2OAc, 2(Gaq′2)).

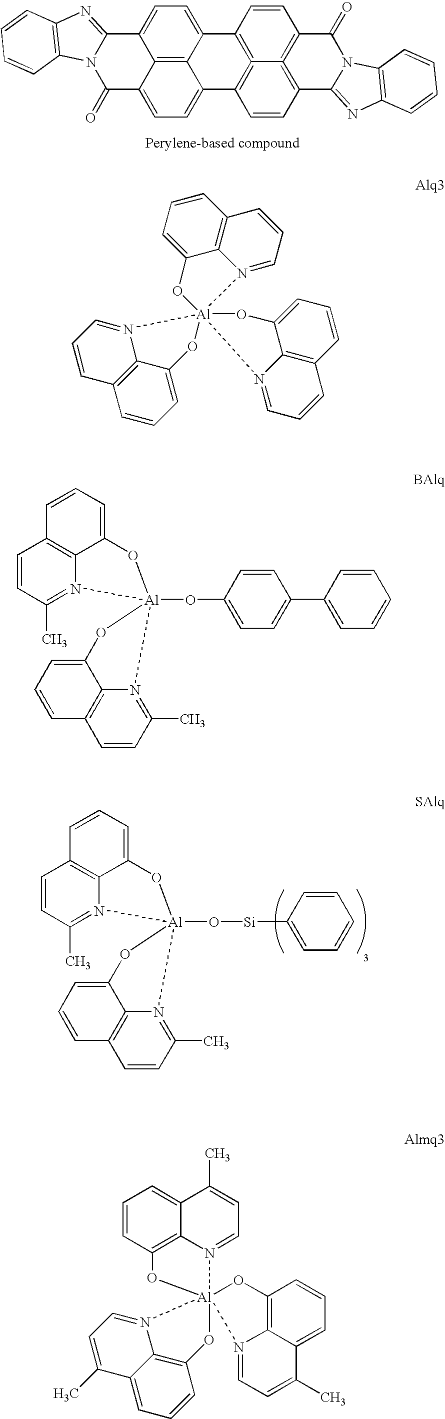

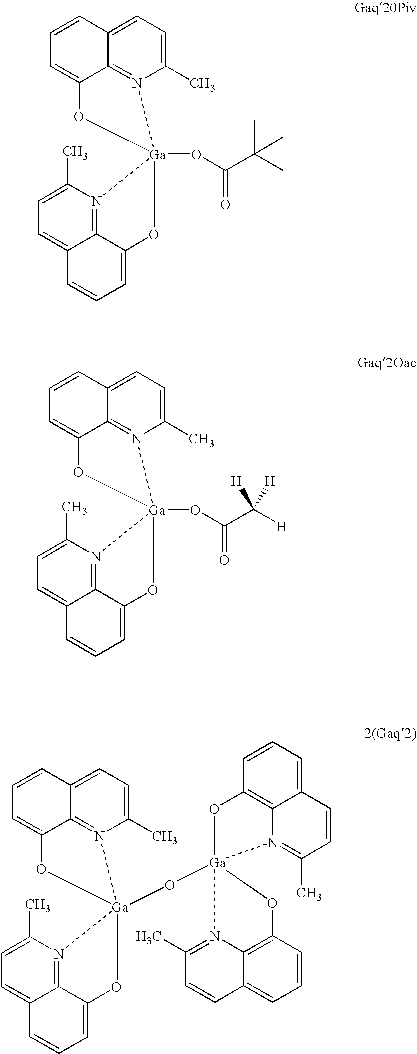

The hole blocking layer may be formed to a thickness of 5 to 100 nm, and the electron transport layer may be formed to a thickness of 5 to 100 nm. If the thicknesses of the hole blocking layer and the electron transport layer are outside the above ranges, electron transport capability and hole blocking capability may be lowered.

Next, a second electrode is formed on the electron transport layer, and the resultant structure is sealed to complete an organic light-emitting device.

A material for forming the second electrode is not particularly limited, and may be metal or alloy with a low work function, e.g., Li, Cs, Ba, Ca, Ca/Al, LiF/Ca, LiF/Al, BaF2/Ca, Mg, Ag, or Al. Alternatively, the second electrode may be a multi-layered structure made of the above-illustrated metals or alloys. The thickness of the second electrode may be 50 to 3,000 Å.

An organic light-emitting device according to the present invention can be manufactured without using a special apparatus or method. That is, an organic light-emitting device according to the present invention can be manufactured by a known organic light-emitting device manufacturing method using a conducting polymer composition.

Hereinafter, the present invention will be described more specifically with reference to the following examples. The following examples are for illustrative purposes and are not intended to limit the scope of the invention.

### PREPARATION EXAMPLE 1

### Preparation of PANI Conducting Polymer Composition Solution

PSSA-g-PANI (polystyrenesulfonic acid-graft-polyaniline) was synthesized as a self-doped conducting polymer using a synthesis method known in the art [W. J. Bae et al. Chem. Comm., pp 2768-2769, 2003]. At this time, the weight ratio of the PSSA polymer chain to the grafted PANI chain was 1:0.15. The number average molecular weight of PSSA-g-PANI was 35,000.

Next, 100 parts by weight of the self-doped conducting polymer and 300 parts by weight of an ionic conjugated polymer of Formula 23 below was dissolved in water to a concentration of 1.5 wt %, to thereby obtain a conducting polymer composition solution.

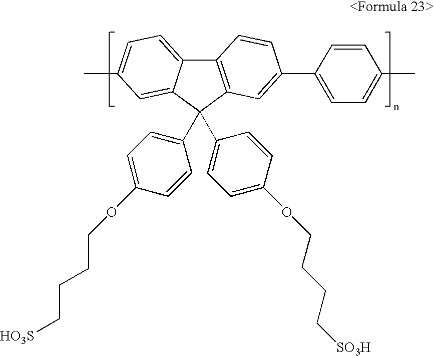

### PREPARATION EXAMPLE 2

### Preparation of PANI Conducting Polymer Composition Solution

A conducting polymer composition solution was prepared in the same manner as in Preparation Example 1 except that a compound of Formula 24 below was further added in an amount of 500 parts by weight based on 100 parts by weight of the conducting polymer, PSSA-g-PANI.

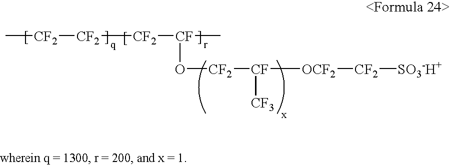

### PREPARATION EXAMPLE 3

### Preparation of PEDOT Conducting Polymer Composition Solution

100 parts by weight of PEDOT-PSS (Baytron P VP Al4083, H. C. Starck) and 600 parts by weight of the ionic conjugated polymer of Formula 23 above were mixed, and the reaction mixture was dissolved in water to a concentration of 1.5 wt %, to thereby obtain a conducting polymer composition solution.

### PREPARATION EXAMPLE 4

### Preparation of PEDOT Conducting Polymer Composition Solution

100 parts by weight of PEDOT-PSS (Baytron P VP Al4083, H. C. Starck) and 300 parts by weight of the ionic conjugated polymer of Formula 23 above were mixed, and the reaction mixture was dissolved in a mixed solvent of water and alcohol (volume ratio of 4.5:5.5). Then, 600 parts by weight of the compound of Formula 24 below, which was dissolved in a mixed solvent of water and alcohol (volume ratio of 4.5:5.5) to a concentration of 1.5 wt %, was added thereto to thereby obtain a conducting polymer composition solution.

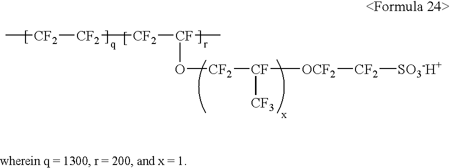

### EXAMPLE 1

A 15 Ω/cm² (150 nm) ITO glass substrate was cut into pieces of 50 mm×50 mm×0.7 mm in size, followed by ultrasonic cleaning in a neutral detergent, pure water, and isopropyl alcohol (15 minutes for each) and then UV/ozone cleaning (30 minutes) to form anodes.

2 wt % of the PSSA-g-PANI-containing conducting polymer composition solution prepared in Preparation Example 1 was spin-coated on the anodes to form hole injection layers with a thickness of 50 nm.

Light-emitting layers were formed to a thickness of 80 nm on the hole injection layers using a green light-emitting material, a polyfluorene-based emissive polymer (Dow Green K2, Dow), and Ba (3.5 nm) and Al (200 nm) were deposited on the light-emitting layers to complete organic light-emitting devices. The organic light-emitting devices were designated as “sample 1”.

### EXAMPLE 2

Organic light-emitting devices were manufactured in the same manner as in Example 1 except that the conducting polymer composition solution prepared in Preparation Example 2 was used as a hole injection layer material. The organic light-emitting devices were designated as “sample 2”.

### EXAMPLE 3

Organic light-emitting devices were manufactured in the same manner as in Example 1 except that the conducting polymer composition solution prepared in Preparation Example 3 was used as a hole injection layer material. The organic light-emitting devices were designated as “sample 3”.

### EXAMPLE 4

Organic light-emitting devices were manufactured in the same manner as in Example 1 except that the conducting polymer composition solution prepared in Preparation Example 4 was used as a hole injection layer material. The organic light-emitting devices were designated as “sample 4”.

### COMPARATIVE EXAMPLE

Organic light-emitting devices were manufactured in the same manner as in Example 1 except that PEDOT-PSS (Baytron P VP Al4083) was used as a hole injection layer material. The organic light-emitting devices were designated as “comparative sample A”.

### EVALUATION EXAMPLE 1—EVALUATION OF WORK FUNCTIONS OF CONDUCTING POLYMER FILMS

The conducting polymer composition solutions prepared in Preparation Examples 1-4 were spin-coated on ITO substrates to form films with a thickness of 50 nm. The films were placed on hot plates and heated at 200° C. in air for 5 minutes to evaluate the work functions of the films. The films were designated as “samples A through D”. The work functions of the films were evaluated using Surface Analyzer Model AC2 (Photoelectron Spectrometer in air (PESA), RIKEN KEIKI, Co. Ltd.). As a result, the work functions of the samples A through D were 5.5 eV, 5.8 eV, 5.55 eV, and 5.85 eV, respectively.

### COMPARATIVE EVALUATION EXAMPLE 1—EVALUATION OF WORK FUNCTIONS OF CONDUCTING POLYMER FILMS

The work functions of films made of Baytron P VP Al4083 (H. C. Starck) as films for AC2 evaluation were evaluated in the same manner as in Evaluation Example 1, and were 5.20 eV. Furthermore, the work functions of the films made of Baytron P VP Al4083, as measured in vacuum using UPS (Ultraviolet Photoelectron Spectroscopy), were 5.15 eV which was similar to that measured in air.

These results show that a film made of a polymer composition according to the present invention can significantly increase a work function according to the type of an ionomer.

### EVALUATION EXAMPLE 2—EVALUATION OF EFFICIENCY CHARACTERISTICS

The efficiencies of the samples 1-4 and the comparative sample A were measured using a SpectraScan PR650 spectroradiometer. The results are presented in Table 1 below.

The samples 1-4 exhibited an efficiency of 10 cd/A or more, and the comparative sample A exhibited an efficiency of 9.5 cd/A.

These results show that an organic light-emitting device including a hole injection layer made of a conducting polymer composition of the present invention has excellent emission efficiency.

### EVALUATION EXAMPLE 3—EVALUATION OF LIFETIME CHARACTERISTICS

The lifetime characteristics of the samples 1-4 and the comparative sample A were evaluated. The lifetime characteristics were evaluated by measuring brightness with respect to time using a photodiode, and can be expressed by time taken to reduce an initial brightness to 50%. The results are presented in Table 1 below.

At an initial brightness of 1,000 cd/m², the samples 1-4 exhibited lifetime characteristics of about 250 to 2,500 hours, and the comparative sample A exhibited lifetime characteristics of about 150 hours. These results show that an organic light-emitting device according to the present invention has a better lifetime than a conventional organic light-emitting device.

TABLE 1

| | | | Lifetime (hr at |
|---|---|---|---|
| HIL | Driving voltage (V) | Efficiency (cd/A) | 1,000 cd/m²) |
| PEDOT-PSS | 2.5 | 9.5 | About 150 |
| Example 1 | 2.4 | 10.2 | About 250 |
| Example 2 | 2.2 | 12.5 | About 700 |
| Example 3 | 2.3 | 10.5 | About 350 |
| Example 4 | 2.2 | 13.5 | About 2,500 |

Referring to Table 1 above, the hole injection layers made of the conducting polymer compositions of the present invention were more excellent in driving voltage, efficiency, and lifetime, as compared with those made of PEDOT/PSS. In particular, the organic light-emitting devices manufactured in Example 4, i.e., further including the perfluorinated ionomer having a different structure from the conducting polymer and the ionic conjugated polymer, exhibited further improved effects.

According to a conducting polymer composition of the present invention, an ionic conjugated polymer used together with a conducting polymer has a conjugated structure, and thus, enhances hole injection and transport capability. Furthermore, ionization potential and work function can be easily adjusted by adjusting the backbone of the ionic conjugated polymer. In addition, the conducting polymer composition of the present invention can be dissolved in water, alcohol, or a polar organic solvent, thereby enabling a solution process and rendering spin-coating easier.

What is claimed is:

1. A conducting polymer composition comprising a conducting polymer and an ionic conjugated polymer.

2. The conducting polymer composition of claim 1, wherein the ionic conjugated polymer has at least one repeat unit selected from the group consisting of polymers represented by Formulae 2a through 2ab and has the degree of polymerization of 2 to 10,000,000: 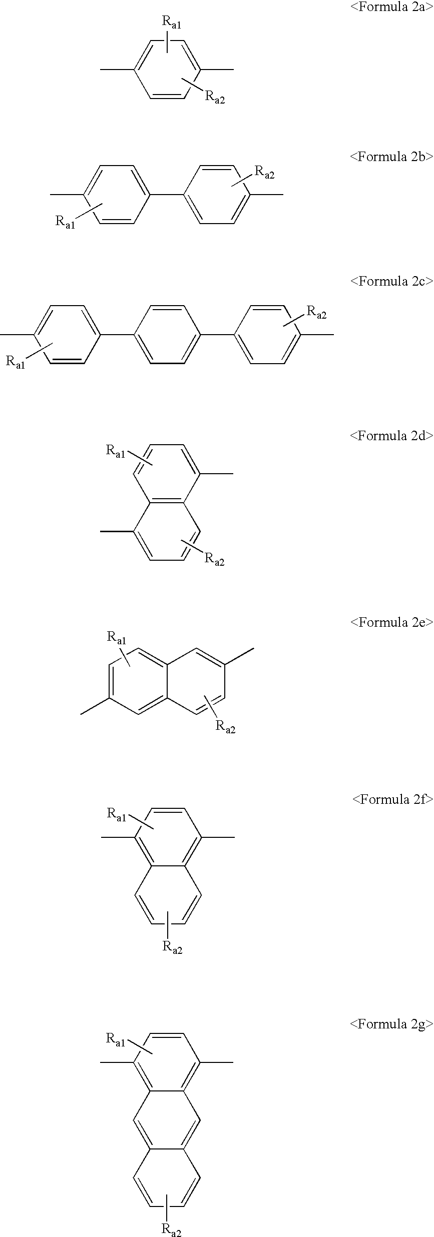 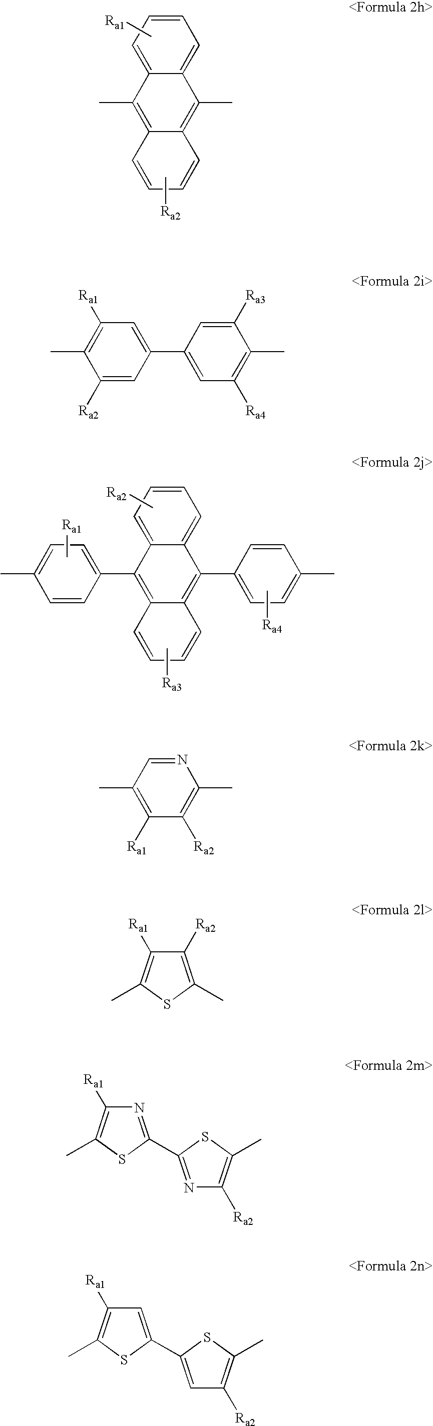 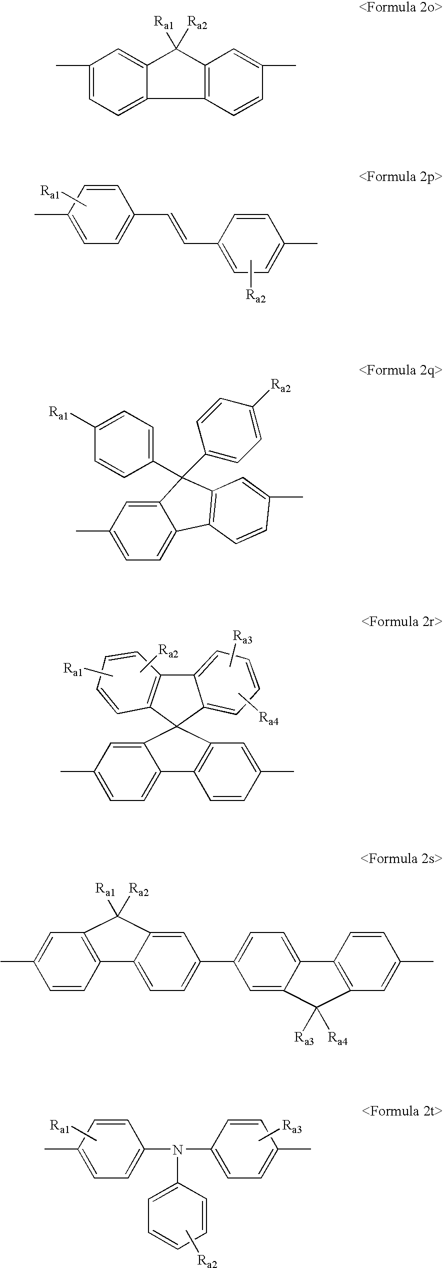 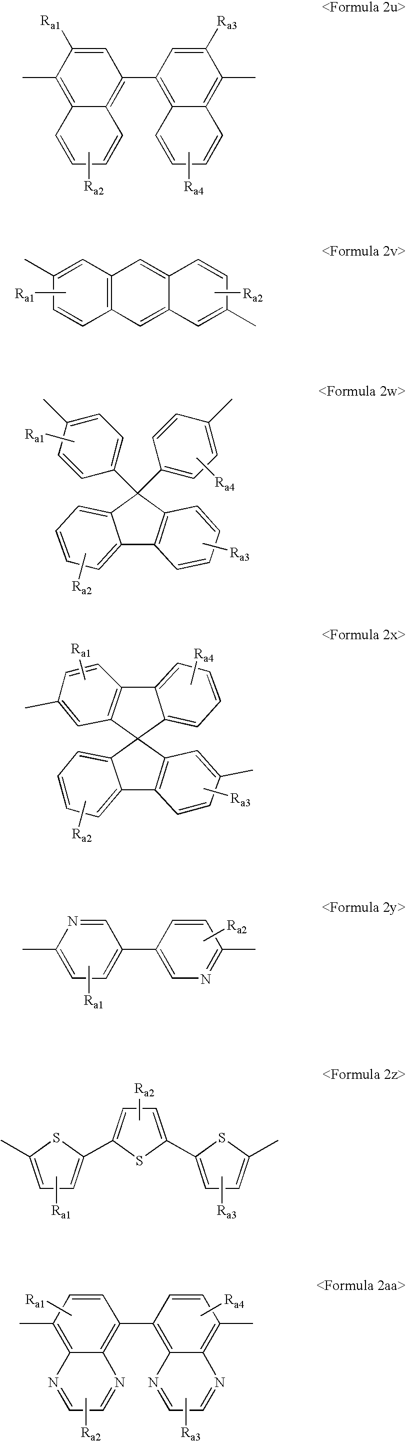 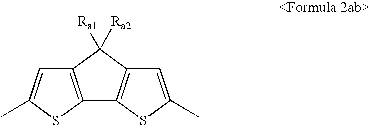
wherein Rₐ₁, Rₐ₂, Rₐ₃, and Rₐ₄ are each independently hydrogen, a C₁-C₁₂ alkyl group, a C₁-C₁₂ alkoxy group, a C₆-C₂₀ aryl group, —N(R′)(R″) where R′ and R″ are each independently hydrogen or a C₁-C₁₂ alkyl group, —R_{c}CO₂R_{b}, —R_{c}SO₃R_{b}, —OR_{c}SO₃R_{b}, or —R_{c}OR_{d}SO₃R_{b} where R_{c} and R_{d} are each a bond or a C₁-C₁₂ alkylene group, and R_{b} is H, Li, K, or Na, and
at least one of Rₐ₁, Rₐ₂, Rₐ₃, and Rₐ₄ is or comprises an ion group.

3. The conducting polymer composition of claim 2, wherein the ion group comprises an anion group selected from the group consisting of PO₃², SO₃—, COO⁻, I⁻, and CH₃COO⁻, and a cation group which is paired with the anion group and selected from the group consisting of metal ions selected from Na⁺, K⁺, Li⁺, Mg⁺², Zn⁺², and Al⁺³, and organic ions selected from H⁺, NH₄⁺, and CH₃(—CH₂—)ₙO+where n is a natural number of 1 to 50.

4. The conducting polymer composition of claim 2, wherein the ionic conjugated polymer is one selected from the group consisting of polymers represented by Formulae 4a through 4f: 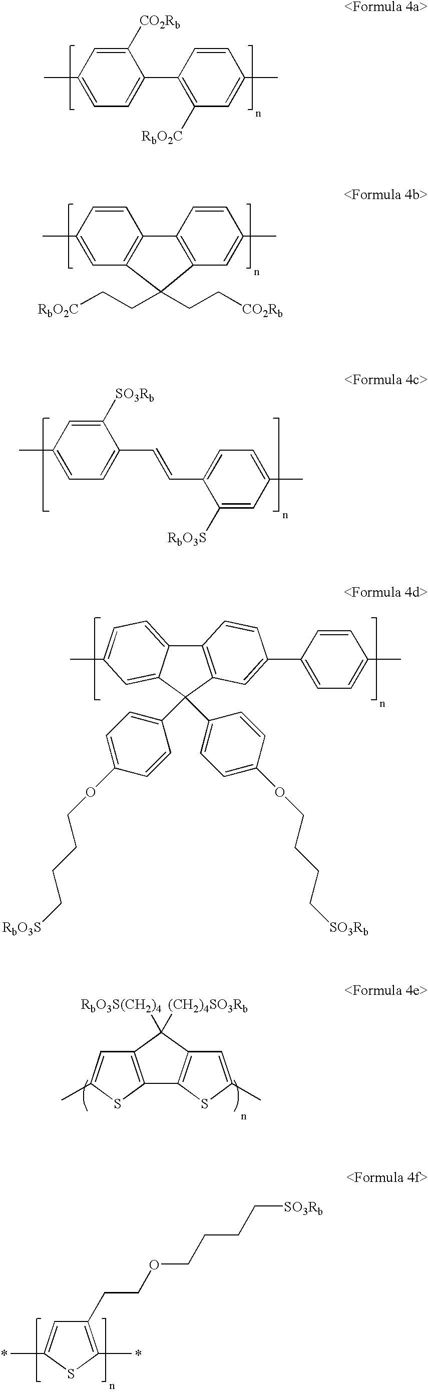
wherein R_{b} is H, Li, K, or Na, and n is the degree of polymerization of 2 to 10,000,000.

5. The conducting polymer composition of claim 2, wherein the ionic conjugated polymer comprises at least one fluorine or at least one fluorine-substituted group.

6. The conducting polymer composition of claim 1, wherein the content of the ionic conjugated polymer is 10 to 3,000 parts by weight based on 100 parts by weight of the conducting polymer.

7. The conducting polymer composition of claim 1, wherein the conducting polymer is at least one selected from the group consisting of polythiophene, poly(3,4-ethylene dioxythiophene) (PEDOT), polyaniline, polypyrrole, polyacetylene, a derivative thereof, and a self-doped conducting polymer having a repeat unit represented by Formula 1 with the degree of polymerization of 10 to 10,000,000: 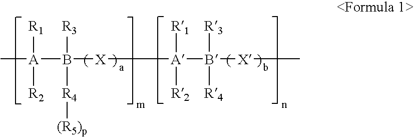
wherein 0<m<10,000,000, 0<n<10,000,000, 0<a<20, 0≦b≦20, and 2≦p≦10,000,000;
at least one of R₁, R₂, R₃, R′₁, R′₂, R′₃, and R′₄ comprises an ion group, and A, B, A′, and B′ are each independently selected from C, Si, Ge, Sn, and Pb;
R₁, R₂, R₃, R′₁, R′₂, R′₃, and R′₄ are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, and hydrogen or a halogen atom is selectively attached to the carbon atoms of the groups;
R₄, X, and X′ are each independently selected from the group consisting of a bond, O, S, a substituted or unsubstituted C₁-C₃₀ alkylene group, a substituted or unsubstituted C₁-C₃₀ iminoalkylene group, a substituted or unsubstituted C₁-C₃₀ heteroalkylene group, a substituted or unsubstituted C₆-C₃₀ arylene group, a substituted or unsubstituted C₆-C₃₀ iminoarylene group, a substituted or unsubstituted C₆-C₃₀ arylalkylene group, a substituted or unsubstituted C₆-C₃₀ alkylarylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, a substituted or unsubstituted C₆-C₃₀ arylester group, and a substituted or unsubstituted C₆-C₃₀ heteroarylester group;
R₅ is a conjugated conducting polymer chain; and
X and X′ are each independently selected from the group consisting of a bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, and a substituted or unsubstituted C₆-C₃₀ arylester group, and hydrogen or a halogen atom is selectively attached to the carbon atoms of the groups.

8. The conducting polymer composition of claim 7, wherein the self-doped conducting polymer is one selected from the group consisting of polymers represented by Formulae 3a through 3c:

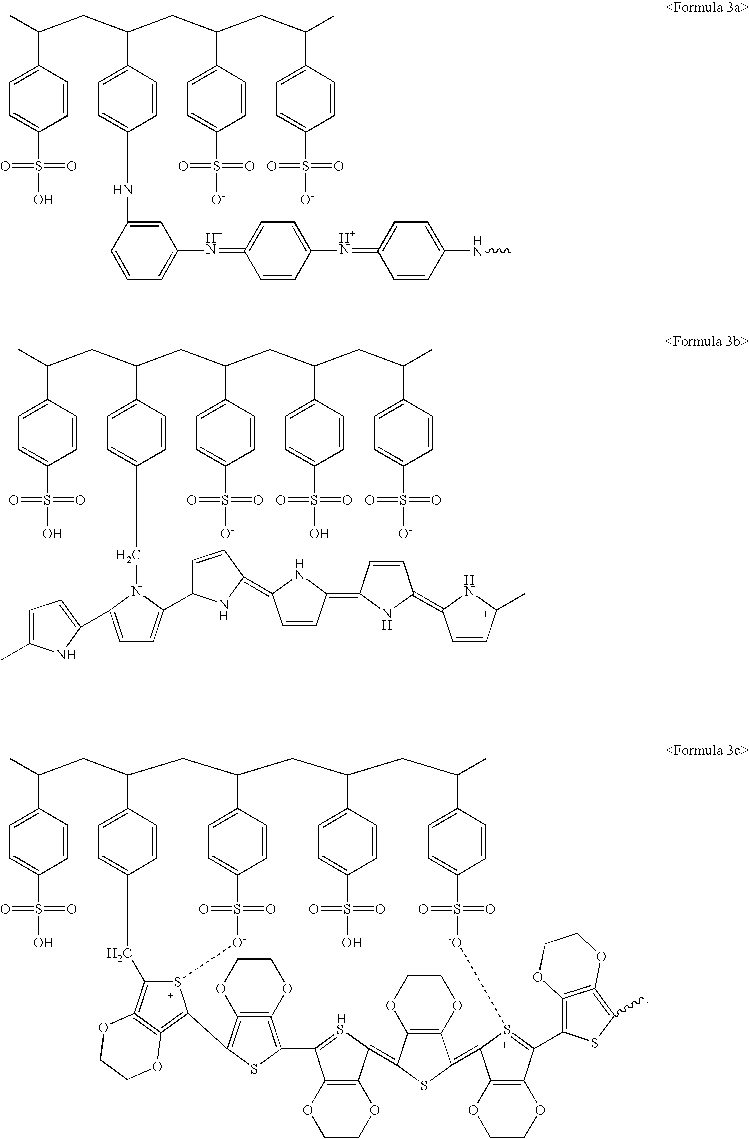

9. The conducting polymer composition of claim 7, wherein the ion group comprises an anion group selected from the group consisting of PO₃², SO₃⁻, COO⁻, I⁻, and CH₃COO⁻, and a cation group which is paired with the anion group and selected from the group consisting of metal ions selected from Na⁺, K⁺, Li⁺, Mg⁺², Zn⁺², and Al⁺³, and organic ions selected from H⁺, NH₄⁺, and CH₃(—CH₂—)ₙO+where n is a natural number of 1 to 50.

10. The conducting polymer composition of claim 7, wherein in the self-doped conducting polymer of Formula 1, at least one of R₁, R₂, R₃, R′₁, R′₂, R′₃, and R′₄ is a fluorine or a fluorine-substituted group.

11. The conducting polymer composition of claim 1, wherein the conducting polymer is a compound represented by Formula 3a and the ionic conjugated polymer is a compound represented by Formula 4d: 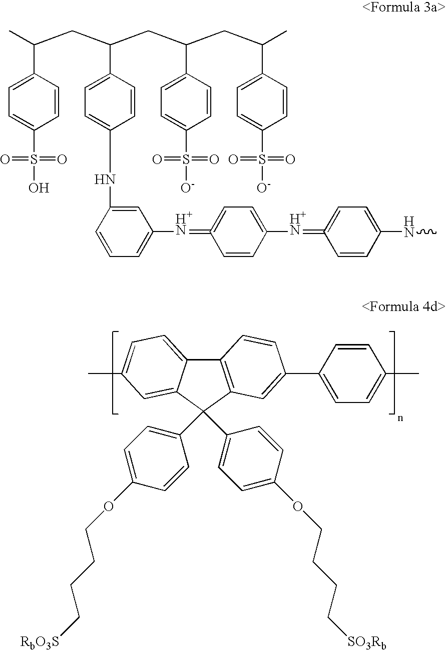
wherein R_{b} is H, Li, K, or Na, and n is the degree of polymerization of 2 to 10,000,000.

12. The conducting polymer composition of claim 1, further comprising an ionomer having a different chemical structure from the ionic conjugated polymer and the ionic conjugated polymer.

13. The conducting polymer composition of claim 12, wherein the ionomer comprises an ion group of a polyacid.

14. The conducting polymer composition of claim 12, wherein the ionomer is a partially fluorinated ionomer or a perfluorinated ionomer.

15. The conducting polymer composition of claim 12, wherein the ionomer has one of repeat units represented by Formulae 5 through 19: 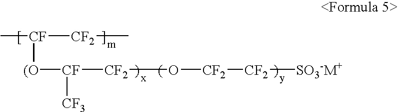
wherein m is a number of 1 to 10,000,000, x and y are each independently a number of 0 to 10, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 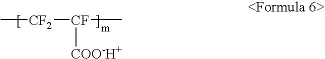
wherein m is a number of 1 to 10,000,000; 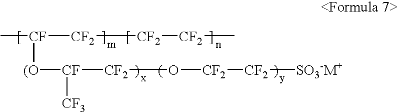
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 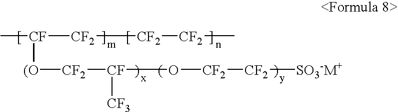
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 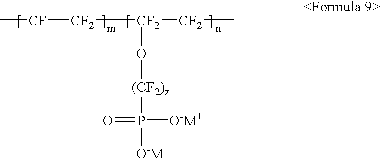
wherein 0<m≦10,000,000, 0≦n<10,000,000, z is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 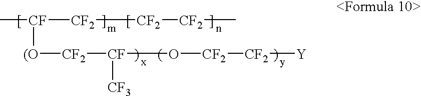
wherein 0<m≦10,000,000, 0≦n<10,000,000, x and y are each independently a number of 0 to 20, and Y is one selected from —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 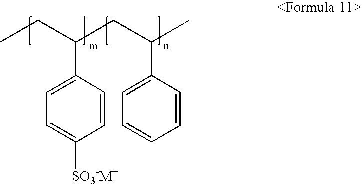
wherein 0<m≦10,000,000, 0≦n<10,000,000, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 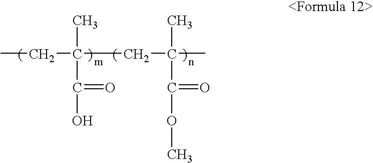
wherein 0<m≦10,000,000 and 0≦n<10,000,000; 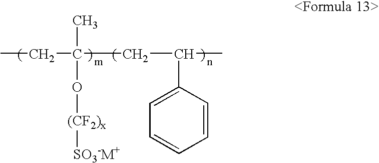
wherein 0<m≦10,000,000, 0≦n<10,000,000, x is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 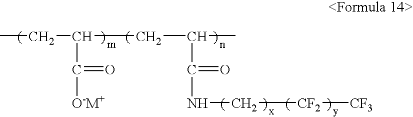
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkvi group of CH₃(CH₂)ₙ⁻ where n is an integer of 0 to 50; 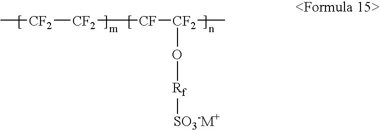
wherein 0≦m<10,000,000, 0<n≦10,000,000, R_{f} is —(CF₂)_{z}— where z is an integer of 1 to 50 except 2, —(CF₂CF₂O)ₙCF₂CF₂— where z is an integer of 1 to 50, or —(CF₂CF₂CF₂O)ₙCF₂CF₂— where z is an integer of 1 to 50, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 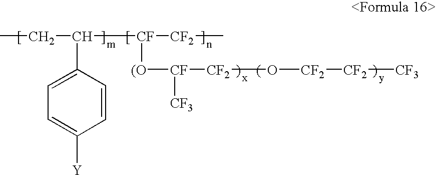
wherein 0≦m<10,000,000, 0<n≦10,000,000, x and y are each independently a number of 0 to 20, and Y is one selected from —SO₃⁻M⁺, —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 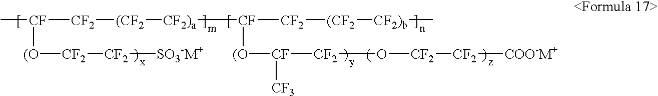
wherein 0<m<10,000,000, 0<n<10,000,000, 0≦a≦20, 0≦b<20, x, y and z are each independently a number of 0 to 5, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is a C₁-C₅, alkyl group; 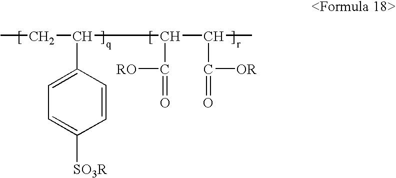
wherein 0≦q<10,000,000, 0<r≦10,000,000, and R is H; and 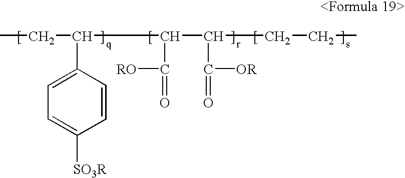
wherein 0≦q<10,000,000, 0<r≦10,000,000, 0<s≦10,000,000, and R is H.

16. The conducting polymer composition of claim 12, wherein the content of the ionomer is 10 to 3,000 parts by weight based on 100 parts by weight of the conducting polymer.

17. The conducting polymer composition of claim 12, wherein the conducting polymer is a compound represented by Formula 3a, the ionic conjugated polymer is a compound represented by Formula 4d, and the ionomer is a compound represented by Formula 8: 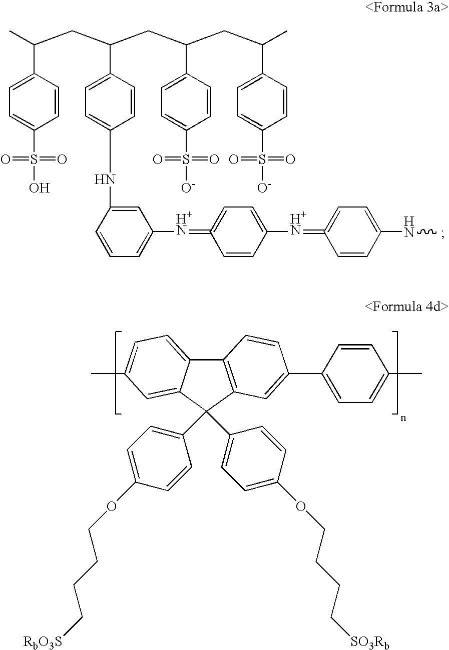
wherein R_{b} is H, Li, K, or Na, and n is the degree of polymerization of 2 to 10,000,000; and 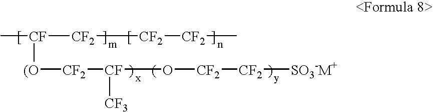
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50.

18. The conducting polymer composition of claim 1, further comprising at least one of a siloxane-based compound and a silsesquioxane-based compound.

19. The conducting polymer composition of claim 18, wherein the siloxane-based compound is a compound represented by Formula 20 or 21: 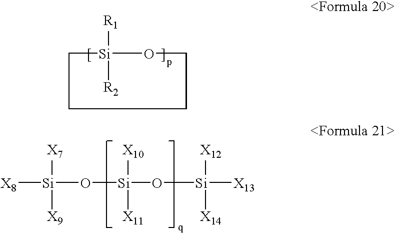
wherein R₁ and R₂ are each independently —CH₂(CH₂)ₘSiX₁X₂X₃, —O—SiX₄X₅X₆, a crosslinkable unit, a hole transport unit, an electron transport unit, an emissive unit, hydrogen, a halogen atom, a C₁-C₂₀ alkyl group, or a C₆-C₃₀ aryl group, and at least one of R₁ and R₂ is —CH₂(CH₂)ₘSiX₁X₂X₃, —O—SiX₄X₅X₆, or a crosslinkable unit;
X₁, X₂, X₃, X₄, X₅, X₆, X₇, X₈, X₉, X₁₀, X₁₁, X₁₂, X₁₃, and X₁₄ are each independently a crosslinkable unit, a hole transport unit, an electron transport unit, an emissive unit, hydrogen, or a C₁-C₂₀ alkyl group, at least one of X₁, X₂, and X₃ is a crosslinkable unit, at least one of X₄, X₅, and X₆ is a crosslinkable unit, and at least one of X₇, X₈, X₉, X₁₀, X₁₁, X₁₂, X₁₃, and X₁₄ is a crosslinkable unit;
p is an integer of 3 to 8;
m is an integer of 1 to 10;
q is 0 or an integer of 1 to 10;
q“X₁₀”s may be the same or different from each other;
q“X₁₁”s may be the same or different from each other;
r“D”s may the same or different from each other; and
r is 0 or an integer of 1 to 10.

20. The conducting polymer composition of claim 18, wherein the silsesquioxane-based compound is a compound represented by Formula 22 below: 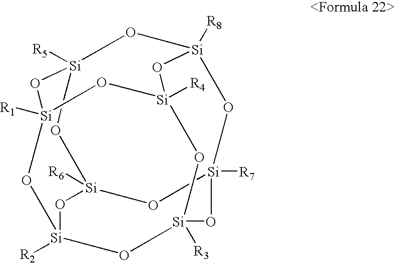
wherein R₁, R₂, R₃, R₄, R₅, R₆, R₇, and R₈ are each independently a hole transport unit, an electron transport unit, or a crosslinkable unit, and at least one of R₁, R₂, R₃, R₄, R₅, R₆, R₇, and R₈ is a crosslinkable unit.

21. The conducting polymer composition of claim 1, further comprising metal nanoparticles, inorganic nanoparticles, or carbon nanotubes as additives.

22. The conducting polymer composition of claim 1, further comprising a chemical crosslinking agent and a physical crosslinking agent to enhance the crosslinkage between the conducting polymer and the ionic conjugated polymer.

23. The conducting polymer composition of claim 1, further comprising at least one of a stabilizer, an ionic liquid, and a compatibilizer.

24. A conductive film formed using the conducting polymer composition of claim 1.

25. An electronic device comprising the conductive film of claim 24.

26. The electronic device of claim 25, which is an organic light-emitting device.

27. The electronic device of claim 25, wherein the conductive film is a hole injection layer.

28. The electronic device of claim 27, which is selected from the group consisting of a photovoltaic device, an electrochromic device, an electrophoretic device, an organic thin film transistor, and an organic memory device.

29. A conducting polymer composition, comprising:
a conducting polymer having at least one selected from the group consisting of polythiophene, poly(3,4-ethylene dioxythiophene), polyaniline, polypyrrole, polyacetylene, a derivative thereof, and a self-doped conducting polymer having a repeat unit represented by Formula 1 with the degree of polymerization of 10 to 10,000,000: 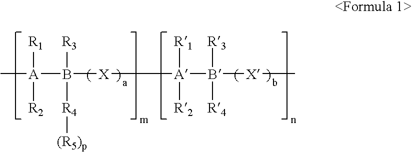
wherein 0<m<10,000,000, 0<n<10,000,000, 0≦a≦20, 0≦b≦20, and 2≦p≦10,000,000;
at least one of R₁, R₂, R₃, R′₁, R′₂, R′₃, and R′₄ comprises an ion group, and A, B, A′, and B′ are each independently selected from C, Si, Ge, Sn, and Pb;
R₁, R₂, R₃, R′₁, R′₂, R′₃, and R′₄ are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, and hydrogen or a halogen atom is selectively attached to the carbon atoms of the groups;
R₄, X, and X′ are each independently selected from the group consisting of a bond, O, S, a substituted or unsubstituted C₁-C₃₀ alkylene group, a substituted or unsubstituted C₁-C₃₀ iminoalkylene group, a substituted or unsubstituted C₁-C₃₀ heteroalkylene group, a substituted or unsubstituted C₆-C₃₀ arylene group, a substituted or unsubstituted C₆-C₃₀ iminoarylene group, a substituted or unsubstituted C₆-C₃₀ arylalkylene group, a substituted or unsubstituted C₆-C₃₀ alkylarylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, a substituted or unsubstituted C₆-C₃₀ arylester group, and a substituted or unsubstituted C₆-C₃₀ heteroarylester group;
R₅ is a conjugated conducting polymer chain; and
X and X′ are each independently selected from the group consisting of a bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, and a substituted or unsubstituted C₆-C₃₀ arylester group, and hydrogen or a halogen atom is selectively attached to the carbon atoms of the groups; and
an ionic conjugated polymer having at least one repeat unit selected from the group consisting of polymers represented by Formulae 2a through 2ab and having the degree of polymerization of 2 to 10,000,000: 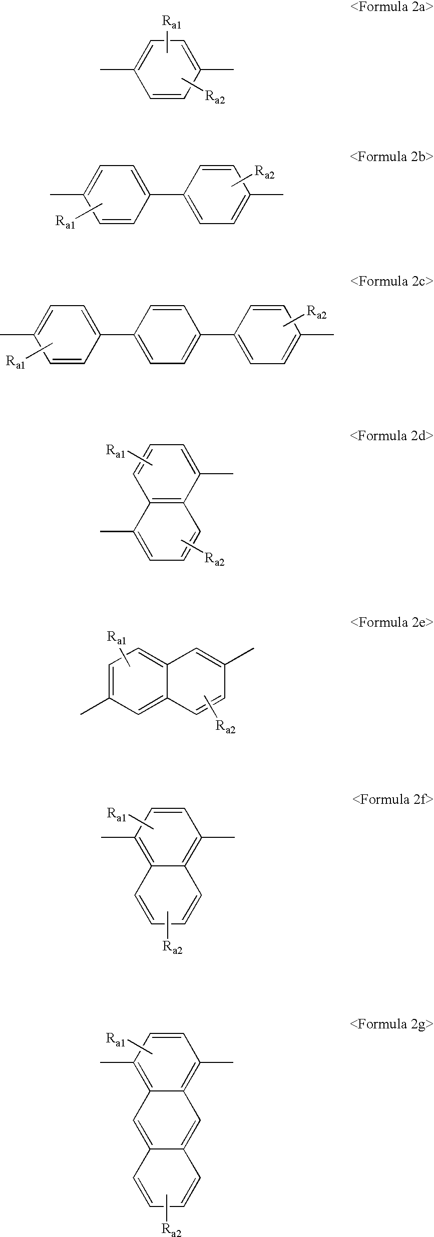 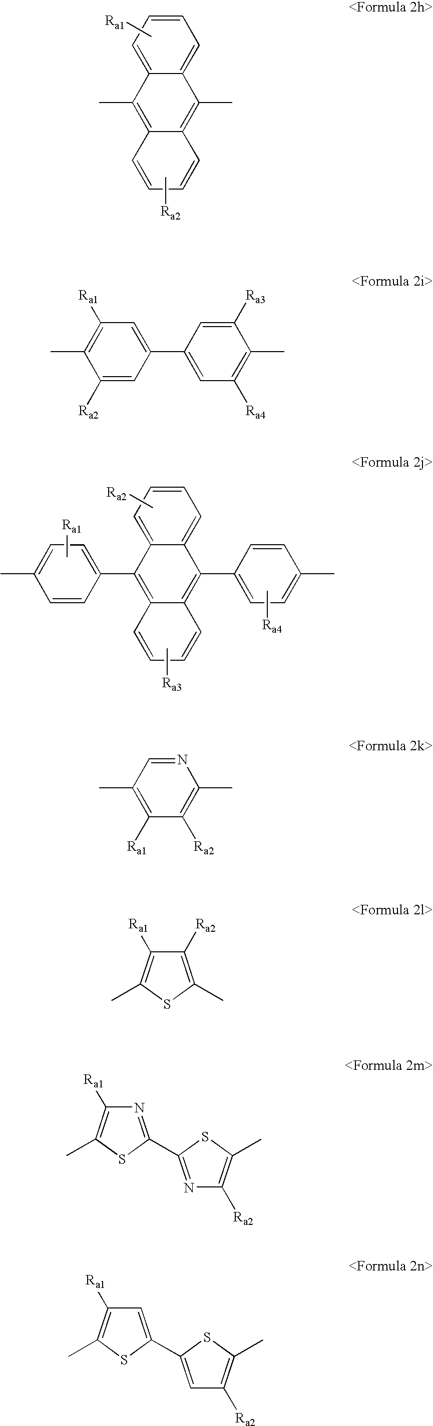 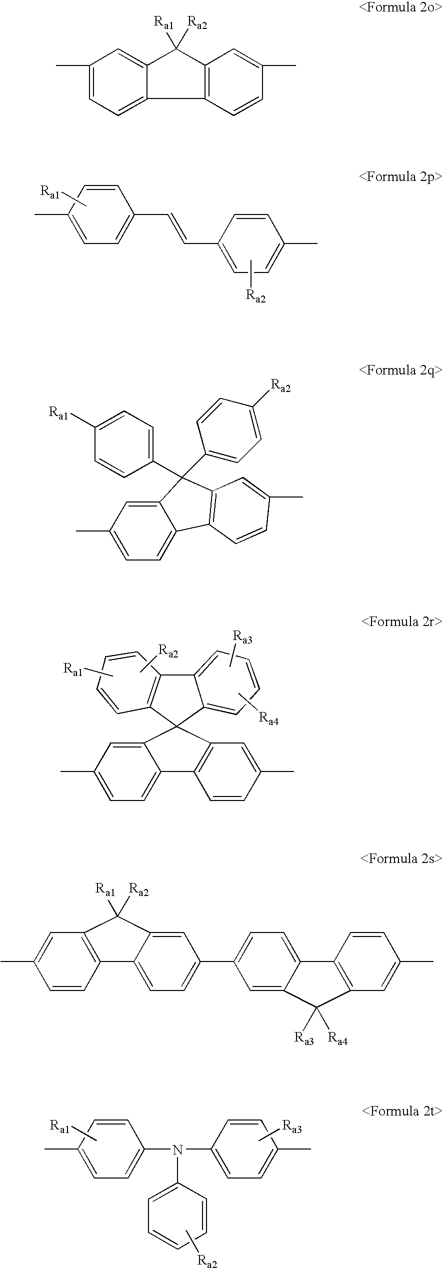 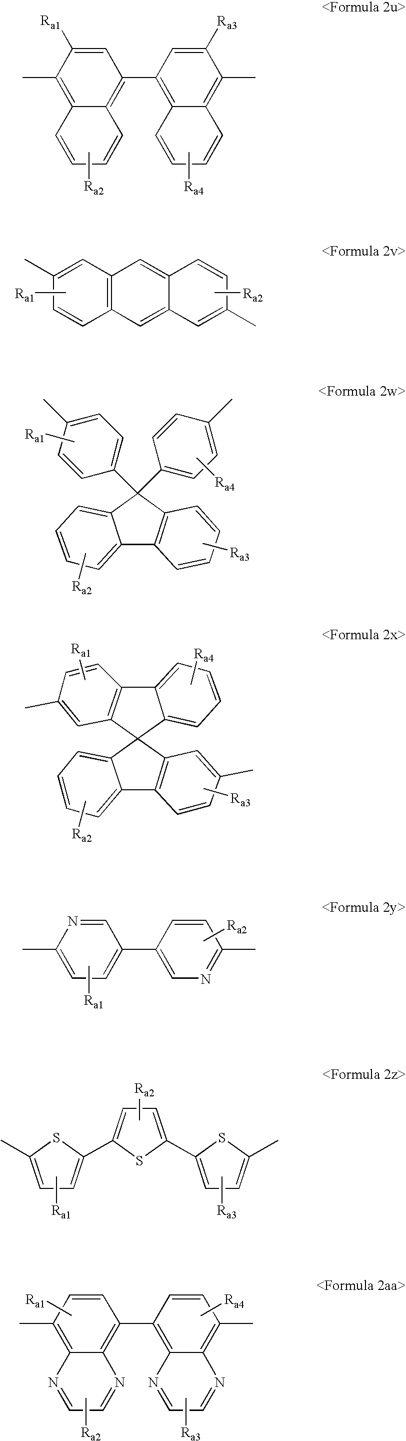 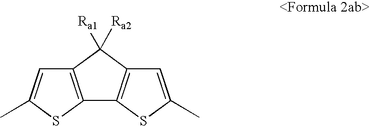
wherein Rₐ₁, Rₐ₂, Rₐ₃, and Rₐ₄ are each independently hydrogen, a C₁-C₁₂ alkyl group, a C₁-C₁₂ alkoxy group, a C₆-C₂₀ aryl group, —N(R′)(R″) where R′ and R″ are each independently hydrogen or a C₁-C₁₂ alkyl group, —R_{c}CO₂R_{b}, —R_{c}SO₃R_{b}, —OR_{c}SO₃R_{b}, or —R_{c}OR_{d}SO₃R_{b} where R_{c} and R_{d} are each a bond or a C₁-C₁₂ alkylene group, and R_{b} is H, Li, K, or Na, and
at least one of Rₐ₁, Rₐ₂, Rₐ₃, and Rₐ₄ is or comprises an ion group.

30. The conducting polymer composition of claim 29, wherein the content of the ionic conjugated polymer is 10 to 3,000 parts by weight based on 100 parts by weight of the conducting polymer.

31. The conducting polymer composition of claim 29, further comprising an ionomer having a different chemical structure from the ionic conjugated polymer and the ionic conjugated polymer, the ionomer having one of repeat units represented by Formulae 5 through 19: 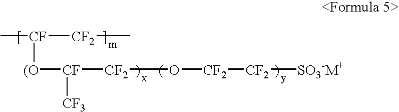
wherein m is a number of 1 to 10,000,000, x and y are each independently a number of 0 to 10, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 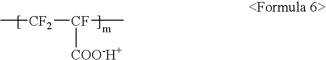
wherein m is a number of 1 to 10,000,000; 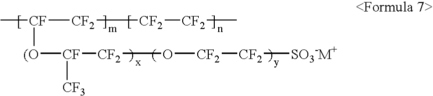
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 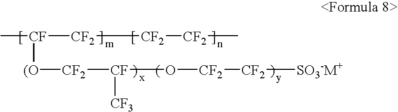
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 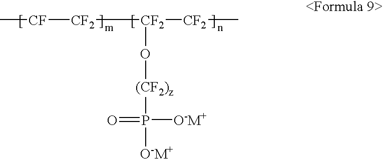
wherein 0<m≦10,000,000, 0≦n<10,000,000, z is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 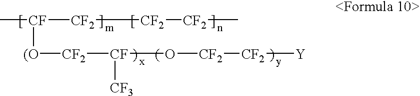
wherein 0<m≦10,000,000, 0≦n<10,000,000, x and y are each independently a number of 0 to 20, and Y is one selected from —COO⁻M⁺, —SO₃⁻NHSO₂CF₃⁺, and —PO₃²⁻(M⁺)₂ where M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 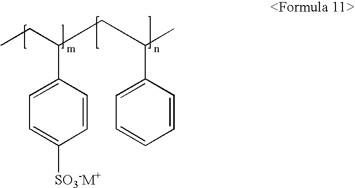
wherein 0<m≦10,000,000, 0≦n<10,000,000, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 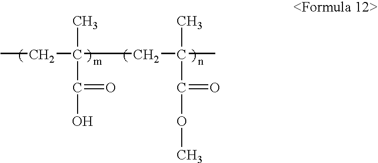
wherein 0<m≦10,000,000 and 0≦n<10,000,000; 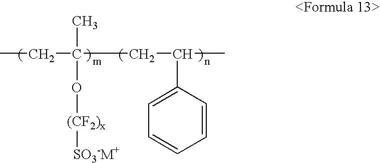
wherein 0<m≦10,000,000, 0≦n<10,000,000, x is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 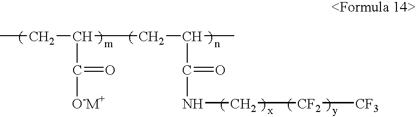
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 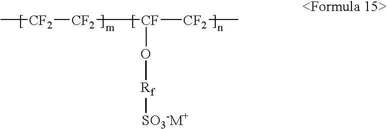
wherein 0≦m<10,000,000, 0<n≦10,000,000, R_{f} is —(CF₂)_{z}— where z is an integer of 1 to 50 except 2, —(CF₂CF₂O)ₙCF₂CF₂— where z is an integer of 1 to 50, or —(CF₂CF₂CF₂O)ₙCF₂CF₂— where z is an integer of 1 to 50, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 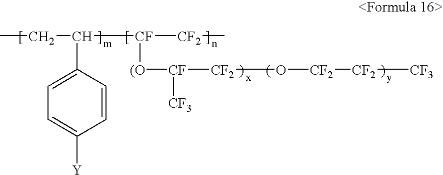
wherein 0≦m<10,000,000, 0<n≦10,000,000, x and y are each independently a number of 0 to 20, and Y is one selected from —SO₃⁻M⁺, —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 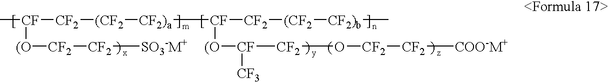
wherein 0<m<10,000,000, 0<n<10,000,000, 0≦a≦20, 0≦b≦20, x, y and z are each independently a number of 0 to 5, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is a C₁-C₅₁ alkyl group; 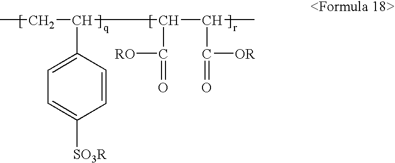
wherein 0≦q<10,000,000, 0<r≦10,000,000, and R is H; and 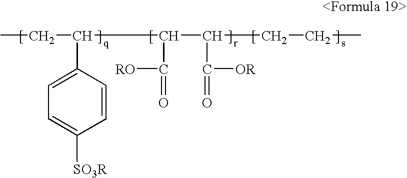
wherein 0≦q<10,000,000, 0<r≦10,000,000, 0<s≦10,000,000, and R is H.

32. The conducting polymer composition of claim 31, wherein the content of the ionomer is 10 to 3,000 parts by weight based on 100 parts by weight of the conducting polymer.

33. An organic light emitting device, comprising:
a first electrode;
a second electrode;
an emissive layer between the first electrode and the second electrode; and
a conductive layer between the first electrode and the emissive layer, the conductive layer formed of a conducting polymer composition comprising a conducting polymer and an ionic conjugated polymer.

34. The organic light emitting device of claim 33, wherein the conducting polymer composition comprises:
the conducting polymer having at least one selected from the group consisting of polythiophene, poly(3,4-ethylene dioxythiophene), polyaniline, polypyrrole, polyacetylene, a derivative thereof, and a self-doped conducting polymer having a repeat unit represented by Formula 1 with the degree of polymerization of 10 to 10,000,000: 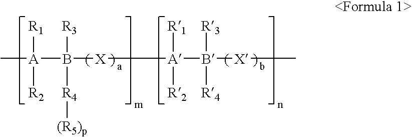
wherein 0<m<10,000,000, 0<n<10,000,000, 0≦a≦20, 0≦b≦20, and 2≦p≦10,000,000;
at least one of R₁, R₂, R₃, R′₁, R′₂, R′₃, and R′₄ comprises an ion group, and A, B, A′, and B′ are each independently selected from C, Si, Ge, Sn, and Pb;
R₁, R₂, R₃, R′₁, R′₂, R′₃, and R′₄ are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, and hydrogen or a halogen atom is selectively attached to the carbon atoms of the groups;
R₄, X, and X′ are each independently selected from the group consisting of a bond, O, S, a substituted or unsubstituted C₁-C₃₀ alkylene group, a substituted or unsubstituted C₁-C₃₀ iminoalkylene group, a substituted or unsubstituted C₁-C₃₀ heteroalkylene group, a substituted or unsubstituted C₆-C₃₀ arylene group, a substituted or unsubstituted C₆-C₃₀ iminoarylene group, a substituted or unsubstituted C₆-C₃₀ arylalkylene group, a substituted or unsubstituted C₆-C₃₀ alkylarylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, a substituted or unsubstituted C₆-C₃₀ arylester group, and a substituted or unsubstituted C₆-C₃₀ heteroarylester group;
R₅ is a conjugated conducting polymer chain; and
X and X′ are each independently selected from the group consisting of a bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₂-C₃₀ heterocycloalkylene group, and a substituted or unsubstituted C₆-C₃₀ arylester group, and hydrogen or a halogen atom is selectively attached to the carbon atoms of the groups; and
the ionic conjugated polymer having at least one repeat unit selected from the group consisting of polymers represented by Formulae 2a through 2ab and having the degree of polymerization of 2 to 10,000,000: 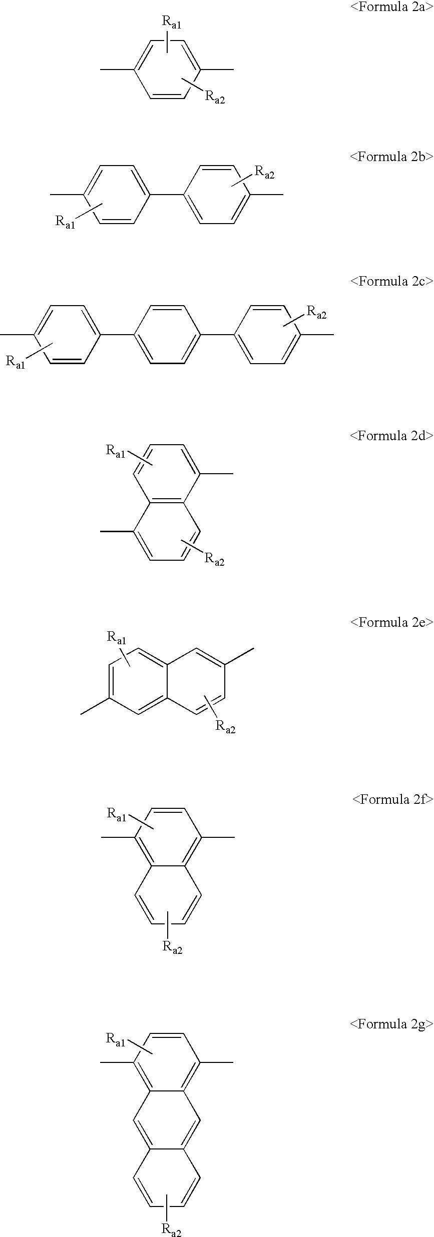 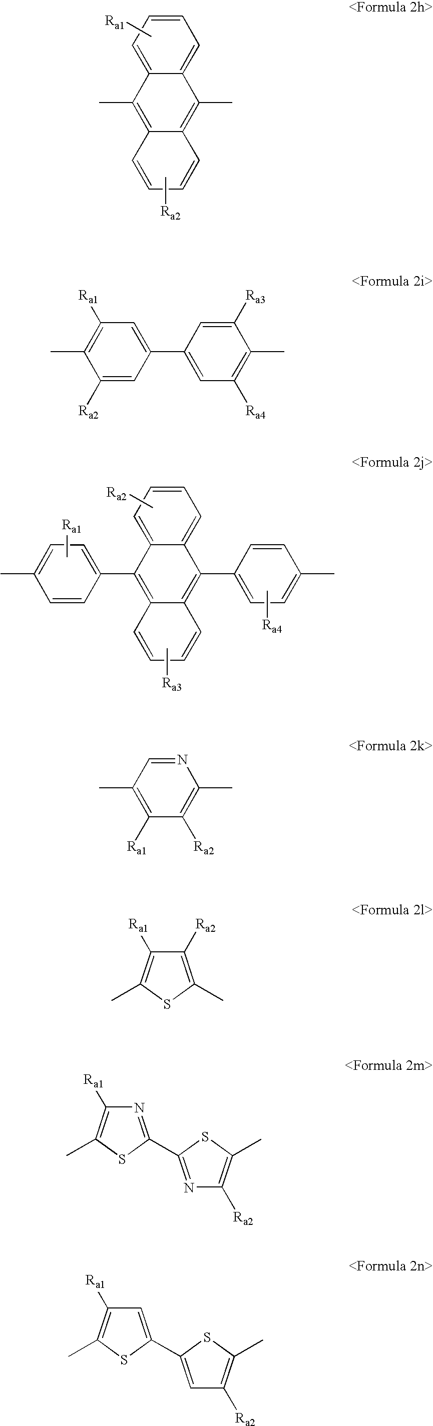 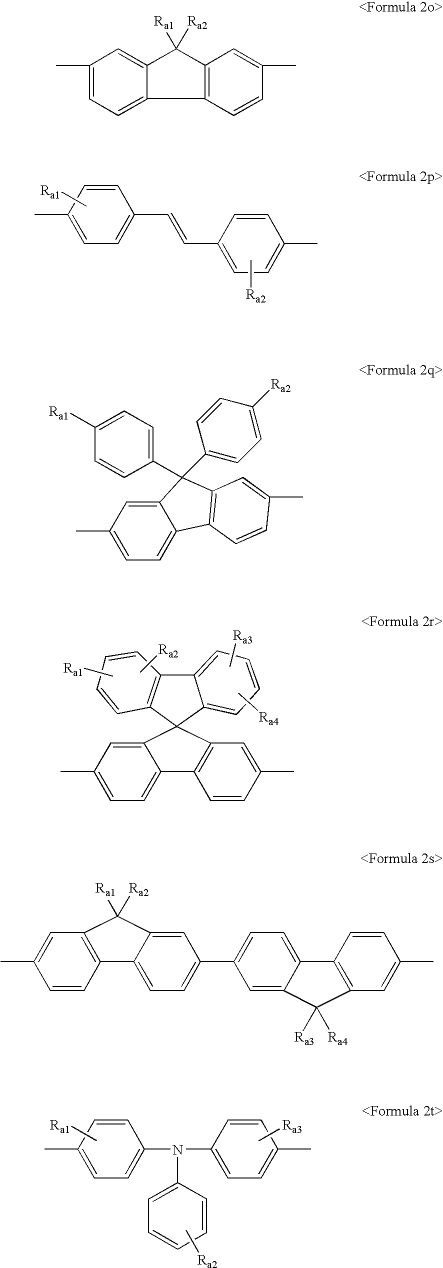 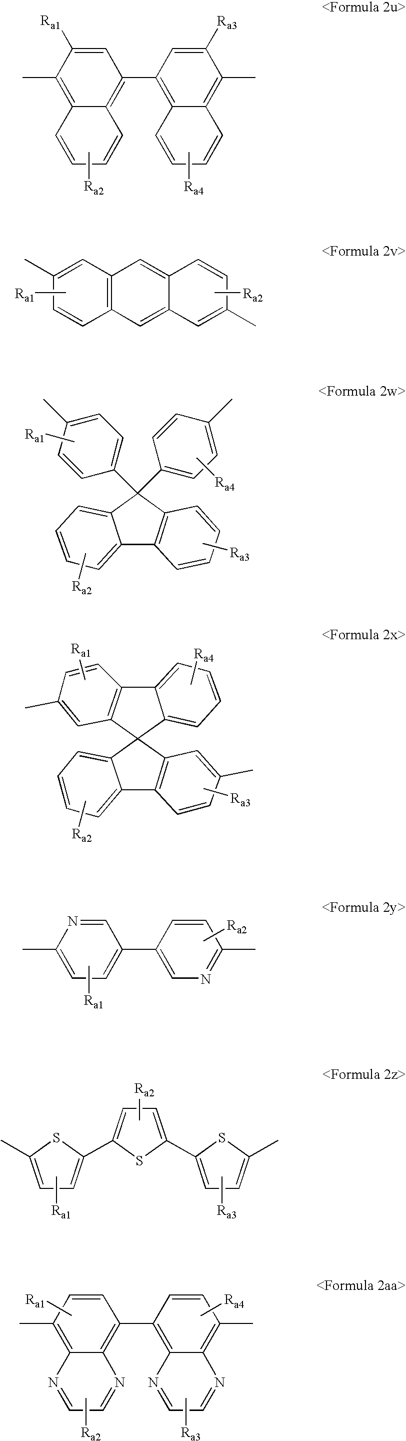 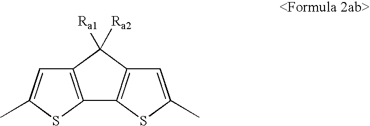
wherein Rₐ₁, Rₐ₂, Rₐ₃, and Rₐ₄ are each independently hydrogen, a C₁-C₁₂ alkyl group, a C₁-C₁₂ alkoxy group, a C₆-C₂₀ aryl group, —N(R′)(R″) where R′ and R″ are each independently hydrogen or a C₁-C₁₂ alkyl group, —R_{c}CO₂R_{b}, —R_{c}SO₃R_{b}, —OR_{c}SO₃R_{b}, or —R_{c}OR_{d}SO₃R_{b} where R_{c} and R_{d} are each a bond or a C₁-C₁₂ alkylene group, and R_{b} is H, Li, K, or Na, and
at least one of Rₐ₁, Rₐ₂, Rₐ₃, and Rₐ₄ is or comprises an ion group.

35. The organic light emitting device of claim 33, further comprising an ionomer having a different chemical structure from the ionic conjugated polymer and the ionic conjugated polymer, the ionomer having one of repeat units represented by Formulae 5 through 19: 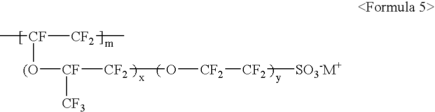
wherein m is a number of 1 to 10,000,000, x and y are each independently a number of 0 to 10, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 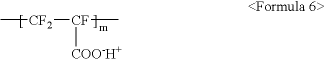
wherein m is a number of 1 to 10,000,000; 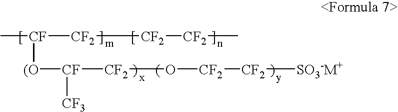
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 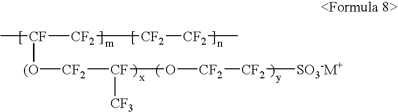
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 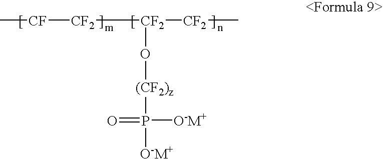
wherein 0<m≦10,000,000, 0≦n<10,000,000, z is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 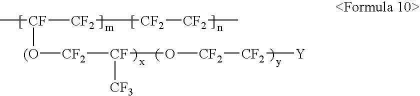
wherein 0<m≦10,000,000, 0≦n<10,000,000, x and y are each independently a number of 0 to 20, and Y is one selected from —COO⁻M⁺, —SO₃⁻NHSO₂CF3⁺, and —PO₃²⁻(M⁺)₂ where M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 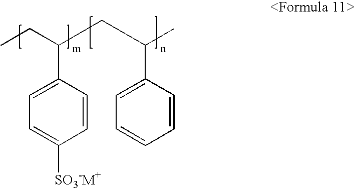
wherein 0<m≦10,000,000, 0≦n<10,000,000, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 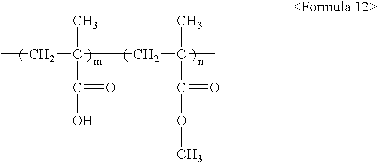
wherein 0<m≦10,000,000 and 0≦n<10,000,000; 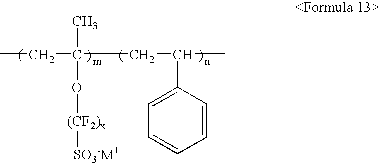
wherein 0<m≦10,000,000, 0≦n<10,000,000, x is a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 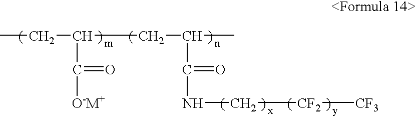
wherein 0<m≦10,000,000, 0≦n<10,000,000, x and y are each independently a number of 0 to 20, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 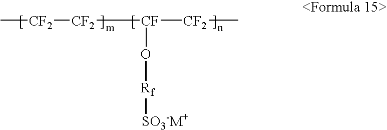
wherein 0≦m<10,000,000, 0<n≦10,000,000, R_{f} is —(CF₂)ₙ— where z is an integer of 1 to 50 except 2, —(CF₂CF₂O)ₙCF₂CF₂— where z is an integer of 1 to 50, or —(CF₂CF₂CF₂O)ₙCF₂CF₂— where z is an integer of 1 to 50, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 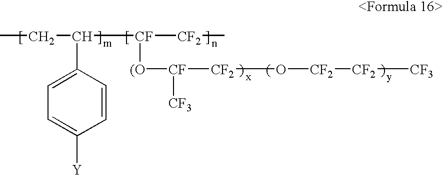
wherein 0≦m<10,000,000, 0<n≦10,000,000, x and y are each independently a number of 0 to 20, and Y is one selected from —SO₃⁻M⁺, —COO⁻M⁺, —SO₃—NHSO₂CF3⁺, and —PO₃²⁻(M⁺)₂ where M⁺ is Na⁺, K⁺, Li⁺, H⁺, CH₃(CH₂)ₙNH₃+where n is an integer of 0 to 50, NH₄⁺, NH₂⁺, NHSO₂CF₃⁺, CHO⁺, C₂H₅OH⁺, CH₃OH⁺, or RCHO⁺ where R is an alkyl group of CH₃(CH₂)ₙ⁻ where n is an integer of 0 to 50; 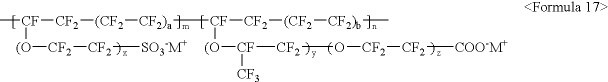
wherein 0<m<10,000,000, 0<n<10,000,000, 0≦a≦20, 0≦b≦20, x, y and z are each independently a number of 0 to 5, and M⁺ is Na⁺, K⁺, Li⁺, H⁺, CH₃(CH₂)ₙNH₃⁺ where n is an integer of 0 to 50, NH₄⁺, NH₂⁺, NHSO₂CF₃⁺, CHO⁺, C₂H₅OH⁺, CH₃OH⁺, or RCHO⁺ where R is a C₁-C₅, alkyl group; 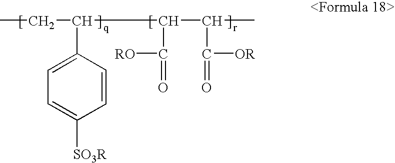
wherein 0≦q<10,000,000, 0<r≦10,000,000, and R is H; and 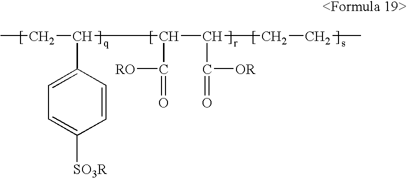
wherein 0≦q<10,000,000, 0<r≦10,000,000, 0<s≦10,000,000, and R is H.

36. The conducting polymer composition of claim 35, wherein the content of the ionic conjugated polymer is 10 to 3,000 parts by weight based on 100 parts by weight of the conducting polymer, and the content of the ionomer is 10 to 3,000 parts by weight based on 100 parts by weight of the conducting polymer.
